(19) United States
(12) Patent Application Publication
(10) Pub. No.: US 2026/0276709 A1
(43) Pub. Date: Sep. 17, 2026

(54) BATTERY STATE-OF-CHARGE ESTIMATION SYSTEMS AND METHODS

(71) Applicant: Temple University-Of The Commonwealth System of Higher Education, Philadelphia, PA (US)

(72) Inventors: Damoon Soudbakhsh, Philadelphia, PA (US); Yan Wang, Ann Arbor, MI (US); OMIDREZA AHMADZADEH, Philadelphia, PA (US)

(21) Appl. No.: 19/040,960

(22) Filed: Jan. 30, 2025

Related U.S. Application Data
(60) Provisional application No. 63/549,084, filed on Feb. 2, 2024.

(51) Int. Cl. G01R 31/367; G01R 31/374; G01R 31/3842; G01R 31/392; H01M 10/42

(52) U.S. Cl. CPC G01R 31/367; G01R 31/374; G01R 31/3842; G01R 31/392; H01M 10/4285

(57) ABSTRACT

A system and method to evaluate the conditions of energy storage devices, particularly Li-based batteries. The technical solution method is non-invasive, non-destructive, fast, and efficient. It allows evaluation of the state of health and charge status of the battery energy storage systems. It is utilized by applying electrical signals to the batteries and using measurements to create a data-driven model. The model is used to estimate the charge status and eliminate and/or mitigate the need to have a lot of training data (common in other machine learning methods) or information about the batteries (common in physics-based modeling/physics-informed methods).

### CROSS-REFERENCE TO RELATED APPLICATIONS

This application claims priority to U.S. provisional application No. 63/549,084 filed on Feb. 2, 2024, incorporated herein by reference in its entirety.

### STATEMENT REGARDING FEDERALLY SPONSORED RESEARCH OR DEVELOPMENT

This invention was made with government support under N00014-23-1-2612 awarded by the Office of Naval Research. The government has certain rights in the invention.

### BACKGROUND OF THE INVENTION

Energy storage devices such as Li-ion batteries are present in many applications, such as electric vehicles, cell phones, and drones. While the estimation of the state of charge has been the critical factor in realizing their full capacity, the lack of accurate methods to estimate state-of-charge limits their operations at full capacity, especially after they go through several charge/discharge cycles. The current methods rely primarily on information from nominal cells and proprietary information from the manufacturers.

The main methods to estimate SOC can be divided into three groups. First, using Coulomb counting, which is based on the charge (integrating the charge current over time) and sometimes multiplying that by a factor less than one to account for ohmic and other losses. This method assumes a known SOC and adds or subtracts it based on the applied current. Most of the time, discharging the battery to full discharge is used to calibrate the initial (known) SOC. Second, using physics-based models, a model is developed based on the measurements and knowledge of a sample cell, and methods such as Kalman filters and observers are used to estimate the state of charge. Third, a combination of the above methods with a machine learning approach (such as a Neural Network). The methods mentioned above are more accurate with fresh (i.e. new) cells, and they lose accuracy with aging or operations at different temperatures. Therefore, recently machine learning methods have been proposed to mitigate the issue. This approach requires a lot of training data.

Thus there is a need in the art for improved SOC estimation systems and methods.

### SUMMARY OF THE INVENTION

Some embodiments of the invention disclosed herein are set forth below, and any combination of these embodiments (or portions thereof) may be made to define another embodiment.

In one aspect, a battery state-of-charge (SOC) estimation method comprises applying an input to the battery comprising at least one of a voltage, a current, and/or a temperature; receiving battery data from at least one sensor associated with the battery, comprising a battery voltage, a battery current, and/or a battery temperature; applying a model based on governing equations based on electrochemistry of the battery to the received battery data; and calculating an estimated SOC.

In one embodiment, the model is continuously updated and learns overtime.

In one embodiment, the method further comprises calculating, predicting, and/or refining a battery voltage.

In one embodiment, the method further comprises calculating a state-of-health (SOH) of the battery.

In one embodiment, the method is non-invasive.

In one embodiment, method is non-destructive.

In one embodiment, the method is performed on a battery in its operating condition.

In one embodiment, the input is sinusoidal.

In one embodiment, the model comprises a data-driven reduced order nonlinear model.

In one embodiment, the model is built via sparsification via sequentially thresholding ridge regression combined with a joint unscented Kalman filter.

In one embodiment, the model is tuned via a cost function.

In another aspect, a battery state-of-charge (SOC) estimation system comprises at least one sensor associated with a battery; and a computing system communicatively connected to the at least one sensor, comprising a processor and a non-transitory computer-readable medium with instructions stored thereon, which when executed by the processor, perform steps comprising: receiving battery data from at least one sensor associated with the battery due to an input being applied, comprising a battery voltage, a battery current, and/or a battery temperature; applying a model based on governing equations based on electrochemistry of the battery to the received battery data; and calculating an estimated SOC.

In one embodiment, the at least one sensor comprises at least one of a voltage meter, a current meter, a thermometer, an electrical impedance meter, and an electrical resistance meter.

In another aspect, a battery state-of-charge (SOC) estimation method comprises applying an input to a battery comprising at least one of a voltage or a current; receiving battery data from at least one sensor associated with the battery, comprising at least one of a battery voltage, a battery current, and a temperature; and creating a data-driven model of voltage dynamics and SOC dynamics based on applying the received battery data to governing equations of the battery to estimate the SOC.

In one embodiment, the method does not require mapping of SOC to voltage/open circuit voltage, therefore no prior tests to determine such mappings or formulas to relate them are required.

In one embodiment, the models can adapt to new environmental and operational conditions as they go through their life cycle and the method always converge to the correct SOC.

In another aspect, a non-transitory computer readable medium comprises program instructions for causing a computer to perform battery state-of-charge (SOC) estimation method comprising: receiving battery data from at least one sensor associated with the battery due to an input being applied, comprising a battery voltage, a battery current, and/or a battery temperature; applying a model based on governing equations based on electrochemistry of the battery to the received battery data; and calculating an estimated SOC.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 depicts an overview of a state-of-charge (SoC) detection method in accordance with some embodiments.

FIG. 2 depicts an exemplary data-driven model in accordance with some embodiments. Following the creation of the library using training data, it employs a regression method, such as STRidge regression, SR3 (Sparse Relaxed Regularized Regression) and/or STLASSO (Sequentially Thresholded Least Absolute Shrinkage and Selection Operator), to determine active terms for each pair of sparsification parameters. Subsequently, the cost function is computed by evaluating cross-validation error, validation error, and number of active terms (representing sparsity) for each set of sparsification parameters, aiming to identify the most suitable model.

FIG. 3A depicts a block diagram of the augmented battery model with joint unscented Kalman filter in accordance with some embodiments.

FIG. 3B depicts an unscented Kalman filter block diagram in accordance with some embodiments.

FIG. 4 depicts an exemplary algorithm for data-driven estimation of SOC in accordance with some embodiments.

FIG. 5 is a plot depicting voltage versus SOC and the effect of the magnitude of electrical current on the curve in accordance with some embodiments. The plotted values show CCCV discharge curves for different C rates, simulated in a TDFN model.

FIG. 6 is a plot depicting charge/discharge versus SOC with 1 C and 0.1 C rates, and the effect of coulomb efficiency in accordance with some embodiments. The plotted values show CCCV charge discharge curves for different C rates, simulated in a TDFN model.

FIG. 7 is a plot depicting charge/discharge at different temperatures (i.e. temperature dependency) in accordance with some embodiments. The plotted values show CCCV discharge curve for different temperatures, simulated by TDFN model.

FIG. 8 is a plot depicting voltage dynamics UDDS where the voltage is predicted based on input in accordance with some embodiments.

FIG. 9 is a plot depicting voltage prediction versus actual voltage in accordance with some embodiments. The voltage data is corrected due to a noisy measurement.

FIG. 10 is a plot depicting SOC prediction based on measured date in accordance with some embodiments.

FIG. 11 is a plot depicting electrical current utilized for experimentation of the model in accordance with some embodiments.

FIG. 12 is a plot depicting an experimental voltage and SOC cost function versus the number of nonzero terms in the sparse vector of coefficients, where 9 terms offer minimum cost for both, in accordance with some embodiments.

FIGS. 13A-13B are plots depicting cross-validation results of the training data for SOC (FIG. 13A) and voltage (FIG. 13B) in accordance with some embodiments.

FIGS. 14A-14B are plots depicting SOC validation results on US06 drive cycles including a SOC estimation result (FIG. 14A) and a SOC error curve (FIG. 14B) in accordance with some embodiments.

FIG. 15 is a plot depicting voltage validation results on US06 drive cycles in accordance with some embodiments.

FIGS. 16A-16B are plots depicting SOC results on UDDS test including a SOC estimation result (FIG. 16A) and a SOC error curve (FIG. 16B) in accordance with some embodiments.

FIG. 17 is a plot depicting Voltage results on UDDS test data in accordance with some embodiments.

FIGS. 18A-18B are plots depicting SOC estimation results for both US06 and UDDS drive cycle data at 10° C. (FIG. 18A) and 40° C. (FIG. 18B) in accordance with some embodiments.

FIG. 19 depicts an exemplary computing environment in which aspects of the invention may be practiced in accordance with some embodiments.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in battery state-of-charge (SOC) estimation systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, 10%, 5%, 1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

Referring now in detail to the drawings, in which like reference numerals indicate like parts or elements throughout the several views, in various embodiments, presented herein are battery state-of-charge (SOC) estimation systems and methods. The disclosed systems and methods provide a means to accurately estimate the state-of-charge (SOC) at any point of life or operational conditions (such as different operating temperatures) in real-time with or without prior information. In some embodiments, the disclosed systems and methods can be applied to any suitable battery or cell type, including but not limited to, Li-ion, Na-ion, vanadium based, and iron-air batteries, any suitable battery design including but not limited to cylindrical, prismatic, and pouch cells, and at any temperature ranging from −100° C. to 700° C. The methods described above, and similar methods, are not effective for modeling individual cells. Disclosed is a data-driven approach that can learn the response of the energy storage system while it is in operation and use that to estimate the state of charge. The method does not require a long learning time and can adjust and adapt the model based on operating conditions, normal aging, or sudden changes in the system. Furthermore, the disclosed provides novel methods and systems to detect the state of charge (SOC) in energy storage systems, particularly lithium-based batteries. These novel methods enable the evaluation of the charging status of such batteries. The methods are based on applying inputs in the form of voltage or current to Li-ion batteries and measuring current or voltage as the output. The inputs can be in sinusoidal form and used in operando conditions. The measurements will be used to estimate SOC for the charge, discharge, and operational conditions and aging of energy storage systems. The tests are non-destructive, and the estimation can be done while the battery is in its operating condition (operando). Furthermore, the method is adaptive and allows for updating the models during operations in the presence of noise and disturbances.

Further disclosed is a reduced-order nonlinear model for battery energy storage systems (BESS). In contrast to mechanistic models, data-driven models provide precise representations of system dynamics without depending on in-situ measurements and proprietary information. However, these models may perform poorly in unforeseen scenarios due to overfitting training data. In response, disclosed is a physics-inspired, data-driven approach to create model equations of batteries based on their electrochemical processes rather than generic terms. A sparse identification method is employed using sequentially thresholding ridge regression to construct a nonlinear model from electrical current (excitation input) and measured voltage. The formulated problem is to optimize the sparsification parameters as hyperparameters and minimize a cost function that includes training and validation sets and the number of terms as a measure of complexity. The model is enhanced with a joint unscented Kalman filter, which enables the model to work correctly with noisy measured data while correcting the state of charge (SOC) estimation. The model's performance in unseen scenarios is evaluated using urban dynamometer driving schedule (UDDS) data. The identified model achieves a root mean square error of <0.013 for SOC and voltage prediction, demonstrating its effectiveness.

Further disclosed is a data-driven method to discover governing equations pertaining to the state of charge (SOC) and voltage dynamics of BESS. The baseline model uses explicit physics-inspired functions of input/output data functions. Additional nonlinear terms augmented the model, and its order was reduced using a sparsification algorithm. A joint unscented Kalman filter (JUKF) is used to correct the model coefficients and improve the SOC estimation in the presence of noisy voltage measurements.

With increased electrification, the need to efficiently utilize energy storage systems is becoming more critical. Battery management systems (BMS) have been implemented to ensure the safe operation of batteries. One of the important parameters in the battery is the state of charge (SOC), which indicates the remaining energy in the battery. Therefore, accurate SOC information enhances the battery's safety by preventing overcharging/discharging and increases the battery's lifespan and performance. Unfortunately, there is no direct measurement for SOC. Hence, BMS estimates SOC and predicts battery dynamics using battery modeling techniques.

Empirical methods are one of the simplest techniques to estimate SOC, such as coulomb counting (see K. S. Ng, C.-S. Moo, Y.-P. Chen, Y.-C. Hsieh, Enhanced coulomb counting method for estimating state-of-charge and state-of-health of lithium-ion batteries, Applied energy 86 (9) (2009) 1506-1511). It is a computationally affordable technique that uses the integral of current as a measure of charge the battery receives or provides to estimate SOC (see Y. Ghoulam, T. Mesbahi, P. Wilson, S. Durand, A. Lewis, C. Lallement, C. Vagg, Lithium-ion battery parameter identification for hybrid and electric vehicles using drive cycle data, Energies 15 (11) (2022) 4005). However, the accuracy of the coulomb counting is highly dependent on the initial SOC values and precise measurement of current (see Y. Zheng, M. Ouyang, X. Han, L. Lu, J. Li, Investigating the error sources of the online state of charge estimation methods for lithium-ion batteries in electric vehicles, Journal of Power Sources 377 (2018) 161-188). The open circuit voltage (OCV) method is another empirical approach to estimating SOC using the measured battery voltage after a long rest time (see Y. Xing, W. He, M. Pecht, K. L. Tsui, State of charge estimation of lithium-ion batteries using the open-circuit voltage at various ambient temperatures, Applied Energy 113 (2014) 106-115). Despite their simplicity, these methods offer low accuracy and robustness in SOC estimation.

In contrast, there have been some efforts to determine SOC and model the battery's dynamic by considering the electrochemical processes inside the battery (see D. Zhang, S. Dey, L. D. Couto, S. J. Moura, Battery adaptive observer for a single particle model with intercalation-induced stress, IEEE Trans Control Syst Technol 28 (4) (2019) 1363-1377) (see X. Han, M. Ouyang, L. Lu, J. Li, Simplification of physics-based electrochemical model for lithium-ion battery on electric vehicle. Part I: Diffusion simplification and single particle model, J. Power Sources 278 (2015) 802-813) (see S. Park, D. Zhang, R. Klein, S. Moura, Estimation of cyclable lithium for li-ion battery state-of-health monitoring, in: ACC 21, IEEE, 2021, pp. 3094-3101). These models are known as mechanistic models which utilize the chemical and physical equations to express the processes inside the battery analytically. For example, the Pseudo-two-dimensional (P2D) model (see M. Doyle, Modeling of Galvanostatic Charge and Discharge of the Lithium/Polymer/Insertion Cell, Journal of The Electrochemical Society 140 (6) (1993) 1526) describes the battery's dynamic using the first principal method. The thermal dynamic and battery aging have been incorporated into the P2D model (see W. Gu, C. Wang, Thermal-electrochemical modeling of battery systems, Journal of The Electrochemical Society 147 (8) (2000) 2910) (see P. Ramadass, B. Haran, P. M. Gomadam, R. White, B. N. Popov, Development of first principles capacity fade model for li-ion cells, Journal of the Electrochemical Society 151 (2) (2004) A196) (see P. Arora, M. Doyle, R. E. White, Mathematical modeling of the lithium deposition overcharge reaction in lithium-ion batteries using carbon-based negative electrodes, Journal of The Electrochemical Society 146 (10) (1999) 3543) to expand its operating condition. While the P2D model provides a comprehensive representation of battery dynamics, it demands the determination of numerous material and physical parameters (see M. Ecker, T. K. D. Tran, P. Dechent, S. K″abitz, A. Warnecke, D. U. Sauer, Parameterization of a Physico-Chemical Model of a Lithium-Ion Battery: I. Determination of Parameters, J. Electrochem. Soc. 162 (9) (2015) A1836-A1848). Furthermore, the complexity of its equations limits its practical application in real-time situations.

To address these issues, simplified models of the P2D model have been proposed, which reduce the number of parameters to be determined and simplify the equations. For example, single particle model (SPM) (see N. A. Chaturvedi, R. Klein, J. Christensen, J. Ahmed, A. Kojic, Algorithms for advanced battery-management systems, IEEE Control Syst. 30 (3) (2010) 49-68) and their expansions SPM with electrolyte (see S. Park, D. Zhang, R. Klein, S. Moura, Estimation of cyclable lithium for li-ion battery state-of-health monitoring, in: ACC 21, IEEE, 2021, pp. 3094-3101), along with multiple particle model (MPM) (see M. M. Majdabadi, S. Farhad, M. Farkhondeh, R. A. Fraser, M. Fowler, Simplified electrochemical multi-particle model for lifepo4 cathodes in lithium-ion batteries, Journal of Power Sources 275 (2015) 633-643) capture the main battery dynamics while reducing the number of required parameters and simplifying the equations. However, these models still require internal battery parameters that are difficult to measure directly, such as diffusion coefficients. The implementation of these models requires the use of nominal parameter values (see S. Park, D. Kato, Z. Gima, R. Klein, S. Moura, Optimal experimental design for parameterization of an electrochemical lithium-ion battery model, J. Electrochem. Soc. 165 (7) (2018) A1309). Although P2D models and their derivatives provide an in-depth depiction of processes, their accuracy is limited to the phenomena they model (see U. Krewer, F. Roder, E. Harinath, R. D. Braatz, B. Bedurftig, R. Findeisen, Dynamic models of li-ion batteries for diagnosis and operation: a review and perspective, Journal of the electrochemical society 165 (16) (2018) A3656).

Another approach to modeling batteries involves the use of passive electrical components, commonly referred to as equivalent circuit models (ECMs) (see X. Hu, S. Li, H. Peng, A comparative study of equivalent circuit models for Li-ion batteries, Journal of Power Sources 198 (2012) 359-367). ECMs describe battery behavior using measurable variables, such as current and voltage, which reduces the complexity of the model significantly (see X. Lin, Y. Kim, S. Mohan, J. B. Siegel, A. G. Stefanopoulou, Modeling and estimation for advanced battery management, Annual Review of Control, Robotics, and Autonomous Systems 2 (2019) 393-426). To address uncertainties within the identified ECMs and enhance SOC estimation, Kalman filters, and their variants are extensively employed (see H. He, R. Xiong, X. Zhang, F. Sun, J. Fan, State-of-charge estimation of the lithium-ion battery using an adaptive extended Kalman filter based on an improved Thevenin model, IEEE Transactions on vehicular technology 60 (4) (2011) 1461-1469) (see X. Lin, Y. Tang, J. Ren, Y. Wei, State of charge estimation with the adaptive unscented Kalman filter based on an accurate equivalent circuit model, Journal of Energy Storage 41 (2021) 102840) (see C. Jiang, S. Wang, B. Wu, C. Fernandez, X. Xiong, J. Coffie-Ken, A state-of-charge estimation method of the power lithium-ion battery in complex conditions based on adaptive square root extended Kalman filter, Energy 219 (2021) 119603). However, ECMs are limited to defined operating conditions due to the lack of connection to physical principles. Expanding ECM validity in a wide range of operating conditions requires a substantial amount of experimental data under different operating conditions (see A. Sancarlos, M. Cameron, A. Abel, E. Cueto, J.-L. Duval, F. Chinesta, From rom of electrochemistry to ai-based battery digital and hybrid twin, Archives of Computational Methods in Engineering 28 (3) (2021) 979-1015).

Advanced data-driven approaches have been applied to capture complex battery dynamics from measured available data using machine learning and statistical techniques. With the development of machine learning algorithms, data-driven models can accurately predict a battery's parameters such as SOC and state of health (SOH). The support vector machines (see M. A. Patil, P. Tagade, K. S. Hariharan, S. M. Kolake, T. Song, T. Yeo, S. Doo, A novel multistage support vector machine-based approach for li ion battery remaining useful life estimation, Applied energy 159 (2015) 285-297) (see X. Feng, C. Weng, X. He, X. Han, L. Lu, D. Ren, M. Ouyang, Online state-of-health estimation for li-ion battery using partial charging segment based on support vector machine, IEEE Transactions on Vehicular Technology 68 (9) (2019) 8583-8592), neural networks (see E. Chemali, P. J. Kollmeyer, M. Preindl, A. Emadi, State-of-charge estimation of Li-ion batteries using deep neural networks: A machine learning approach, J. Power Sources 400 (2018) 242-255) (see D. N. How, M. A. Hannan, M. S. H. Lipu, K. S. Sahari, P. J. Ker, K. M. Muttaqi, State-of-charge estimation of li-ion battery in electric vehicles: A deep neural network approach, IEEE Transactions on Industry Applications 56 (5) (2020) 5565-5574) (see D. Zhu, J. J. Campbell, G. Cho, Battery voltage prediction using neural networks, in: 2021 IEEE Transportation Electrification Conference & Expo (ITEC), IEEE, 2021, pp. 807-812), and their augmentations such as recurrent neural networks (see C. Vidal, P. Malysz, M. Naguib, A. Emadi, P. J. Kollmeyer, Estimating battery state of charge using recurrent and non-recurrent neural networks, Journal of Energy Storage 47 (2022) 103660) (see R. Zhao, P. J. Kollmeyer, R. D. Lorenz, T. M. Jahns, A compact unified methodology via a recurrent neural network for accurate modeling of lithium-ion battery voltage and state-of-charge, in: 2017 IEEE Energy Conversion Congress and Exposition (ECCE), IEEE, 2017, pp. 5234-5241), convolutional neural network (see X. Fan, W. Zhang, C. Zhang, A. Chen, F. An, Soc estimation of li-ion battery using convolutional neural network with u-net architecture, Energy 256 (2022) 124612), and deep transfer neural networks (see C. Bian, S. Yang, Q. Miao, Cross-domain state-of-charge estimation of li-ion batteries based on deep transfer neural network with multiscale distribution adaptation, IEEE Transactions on Transportation Electrification 7 (3) (2021) 1260-1270) provide input-output relation for predicting batteries' parameters. Although these approaches eliminate the need to measure batteries' parameters, they are highly dependent on the quality of training data and require a large amount of data sequence to construct a stable model (see X. Hu, S. E. Li, Y. Yang, Advanced machine learning approach for lithium-ion battery state estimation in electric vehicles, IEEE Transactions on Transportation Electrification 2 (2) (2016) 140-149). Furthermore, due to the nature of machine learning algorithms, they tend to overfit the training data, leading to physically inexplicable results (see H. Tu, S. Moura, H. Fang, Integrating electrochemical modeling with machine learning for lithium-ion batteries, in: 2021 American Control Conference (ACC), 2021, pp. 4401-4407).

Hybrid models integrate machine learning algorithms with ECMs (see Z. Cui, L. Kang, L. Li, L. Wang, K. Wang, A combined state-of-charge estimation method for lithium-ion battery using an improved bgru network and ukf, Energy 259 (2022) 124933) or mechanistic models (see H. Tu, S. Moura, Y. Wang, H. Fang, Integrating physics-based modeling with machine learning for lithium-ion batteries, Applied Energy 329 (2023) 120289) to utilize the strength of both approaches. For instance, deep learning is employed in ECMs to estimate capacity accurately (see S. Su, W. Li, J. Mou, A. Garg, L. Gao, J. Liu, A hybrid battery equivalent circuit model, deep learning, and transfer learning for battery state monitoring, IEEE Transactions on Transportation Electrification 9 (1) (2022) 1113-1127). Another hybrid model using a thermally coupled ECM with a neural network aims to capture both battery dynamics and temperature (see Q.-K. Wang, Y.-J. He, J.-N. Shen, Z.-F. Ma, G.-B. Zhong, A unified modeling framework for lithium-ion batteries: An artificial neural network based thermal coupled equivalent circuit model approach, Energy 138 (2017) 118-132). These models cover a broad range of operating situations; however, they lack interpretability and demand extensive calibration data. By coupling simplified mechanistic models such as SPM with recurrent neural networks, simplified mechanistic models have been enhanced (see S. Park, D. Zhang, S. Moura, Hybrid electrochemical modeling with recurrent neural networks for li-ion batteries, in: 2017 American control conference (ACC), IEEE, 2017, pp. 3777-3782). Another hybrid model encompasses an SPM, a lumped thermal model, and a neural network for SOC and temperature estimations (see F. Feng, S. Teng, K. Liu, J. Xie, Y. Xie, B. Liu, K. Li, Co-estimation of lithium-ion battery state of charge and state of temperature based on a hybrid electrochemical-thermal-neural-network model, Journal of Power Sources 455 (2020) 227935). However, the hybrid models require internal battery parameters for mechanistic models like SPM and a substantial amount of data for machine-learning components to be trained.

To address the mentioned gap, disclosed herein is a physics-inspired reduced-order data driven model to develop an interpretable and generalizable model of battery. The model architecture is developed by including physics-inspired terms and augmenting sparse identification of nonlinear dynamical systems (SINDγ) (see S. L. Brunton, J. L. Proctor, J. N. Kutz, Discovering governing equations from data by sparse identification of nonlinear dynamical systems, PNAS 113 (15) (2016) 3932-3937) (see O. Ahmadzadeh, R. Rodriguez, Y. Wang, D. Soudbakhsh, A physics inspired machine learning nonlinear model of li-ion batteries, in: 2023 American Control Conference (ACC), IEEE, 2023, pp. 3087-3092) (see D. Soudbakhsh, A. M. Annaswamy, Y. Wang, S. L. Brunton, J. Gaudio, H. Hussain, D. Vrabie, J. Drgona, D. Filev, Data-Driven Control: Theory and Applications, in: ACC'2023, 2023, pp. 1922-1939) and joint unscented Kalman filter (JUKF) (see E. A. Wan, R. Van Der Merwe, The unscented Kalman filter for nonlinear estimation, in: Proceedings of the IEEE 2000 Adaptive Systems for Signal Processing, Communications, and Control Symposium (Cat. No. 00EX373), Ieee, 2000, pp. 153-158).

The augmented SINDy algorithm learns the nonlinear dynamics of the battery by extracting the most important terms from a library of potential through sparsification. In addition, the training of this method requires significantly less data than other models, such as neural networks. SINDy was introduced for autonomous systems (without control input) (see S. L. Brunton, J. L. Proctor, J. N. Kutz, Discovering governing equations from data by sparse identification of nonlinear dynamical systems, PNAS 113 (15) (2016) 3932-3937). Due to its simplicity, it attracted attention and was expanded to include control input (see S. L. Brunton, J. L. Proctor, J. N. Kutz, Sparse identification of nonlinear dynamics with control (SINDYc), IFAC-PapersOnLine 49 (18) (2016) 710-715) (see U. Fasel, E. Kaiser, J. N. Kutz, B. W. Brunton, S. L. Brunton, Sindy with control: A tutorial, in: 2021 60th IEEE Conference on Decision and Control (CDC), IEEE, 2021, pp. 16-21) (see E. Kaiser, J. N. Kutz, S. L. Brunton, Sparse identification of nonlinear dynamics for model predictive control in the low-data limit, Proceedings of the Royal Society A 474 (2219) (2018) 20180335), implicit dynamics (see K. Kaheman, J. N. Kutz, S. L. Brunton, Sindy-pi: a robust algorithm for parallel implicit sparse identification of nonlinear dynamics, Proceedings of the Royal Society A 476 (2242) (2020) 20200279), stability promotion (see A. A. Kaptanoglu, J. L. Callaham, A. Aravkin, C. J. Hansen, S. L. Brunton, Promoting global stability in data-driven models of quadratic nonlinear dynamics, Physical Review Fluids 6 (9) (2021) 094401), robustness to noise (see U. Fasel, J. N. Kutz, B. W. Brunton, S. L. Brunton, Ensemble-sindy: Robust sparse model discovery in the low-data, high-noise limit, with active learning and control, Proceedings of the Royal Society A 478 (2260) (2022) 20210904) (see K. Kaheman, S. L. Brunton, J. N. Kutz, Automatic differentiation to simultaneously identify nonlinear dynamics and extract noise probability distributions from data, Machine Learning: Science and Technology 3 (1) (2022) 015031), and Kalman filter (see J. Wang, J. Moreira, Y. Cao, B. Gopaluni, Time-variant digital twin modeling through the Kalman-generalized sparse identification of nonlinear dynamics, in: 2022 American Control Conference (ACC), IEEE, 2022, pp. 5217-5222). Although SINDy has significant advantages over other data-driven techniques, it has several main drawbacks. These include challenges in selecting the proper terms for the library of candidate terms, tunning sparsification parameters, and, similar to other machine learning methods, noise can deteriorate the performance of the SINDγ.

To address these issues, terms are included in the library inspired by the electrochemical process inside the battery, as opposed to adding numerous generic terms. This allows the library to reflect the battery's electrochemical processes and provides the necessary terms for identifying the battery model. Furthermore, to avoid overfitting and increase generalizability, sparsification parameters are treated as hyperparameters and are tuned using a novel cost function incorporating two data sets instead of the traditional approach using a single data set. Lastly, SINDy is enhanced by integrating it with JUKF to reduce the measurement noise effect. JUKF uses noisy measured voltage data to refine voltage data, consequently improving SOC estimation. The SINDy algorithm needs the correct initial value to predict the time series data, and it fails to predict the actual value with an inaccurate initial value as it does not update and get any information from the output. By augmenting SINDy with JULK, the model converges to the actual value with inaccurate information about the initial value. Therefore the main contributions of the work include enriching the SINDy library by including physics-inspired terms, introducing a novel cost function for tunning sparsification parameters to avoid overfitting training data, and enhancing SINDy by integrating it with joint unscented Kalman filter to mitigate noise effect and enable robust prediction, even with inaccurate information.

Referring now to the figures, exemplary systems and methods are described. The disclosed systems and methods utilize sensors such as voltage, current, and temperature sensors to create a model of the energy storage system. A model is used to predict the voltage and estimate the battery's state of charge. Information such as temperature readings can be used to improve the estimation.

There are various ways that the model can be created, such as using the standard inputs to the system (operando), using a designed excitation to create the model while the battery is not in use, and/or using an excitation input while the battery is in operation and separate the responses for the modeling.

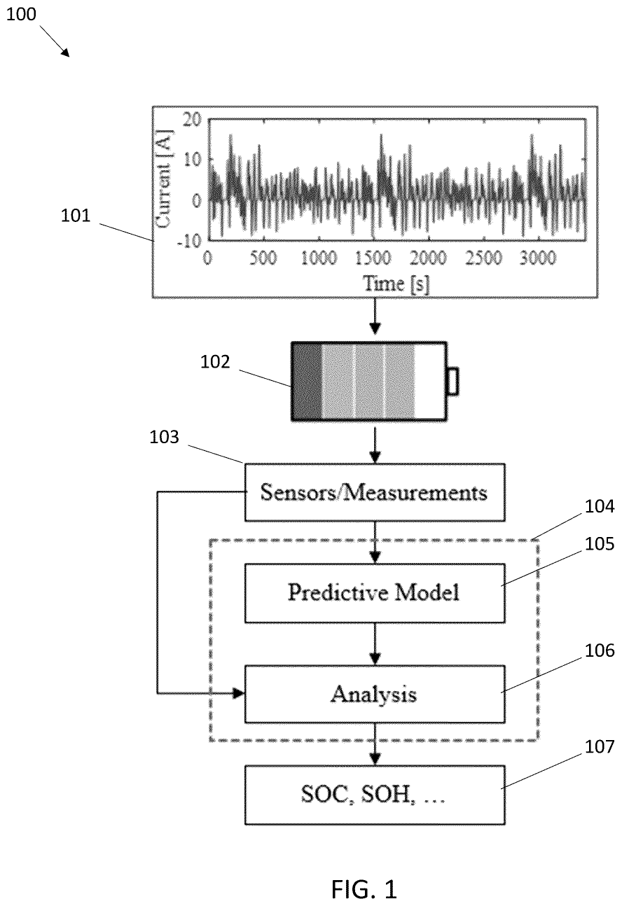

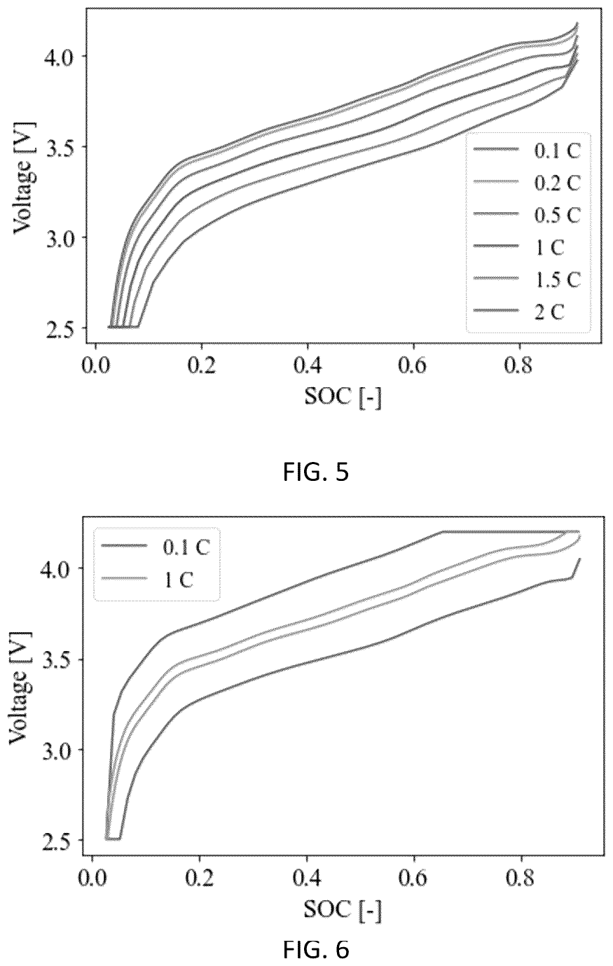

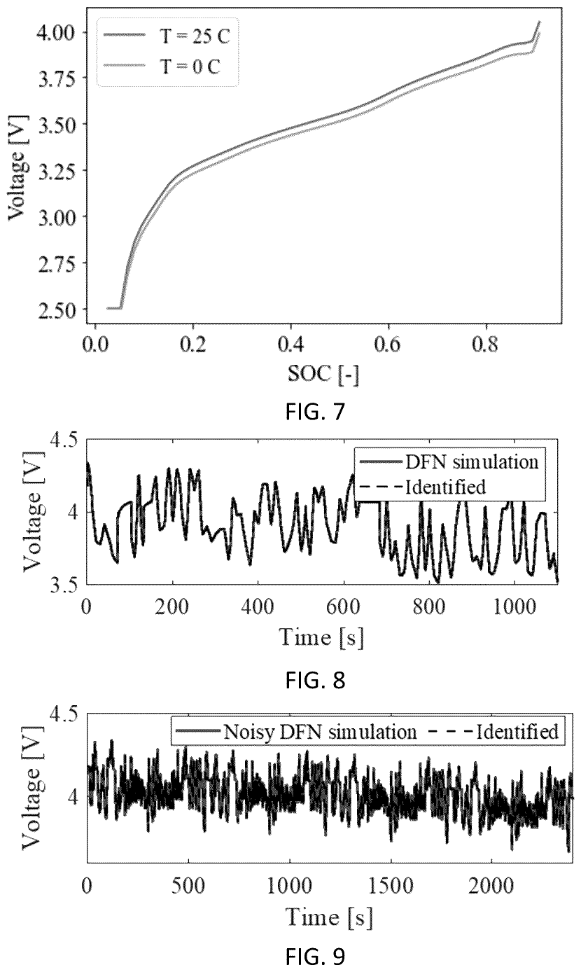

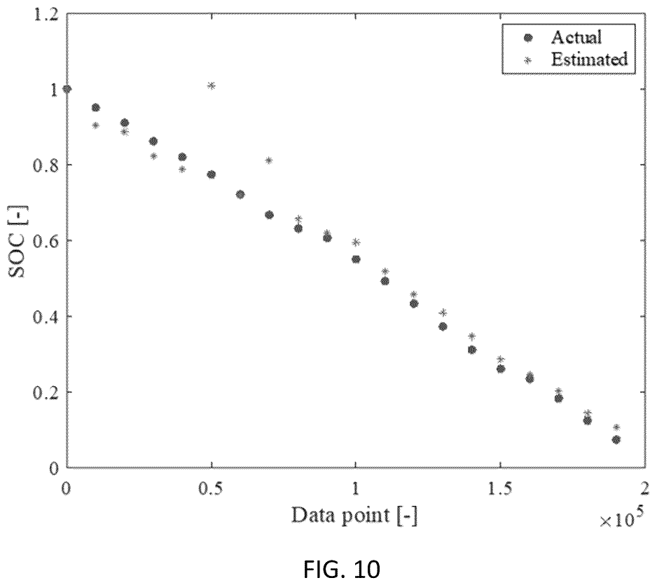

FIG. 1 demonstrates a schematic of the method to create a model and predict the residual charge of the system. In some embodiments, the PyBaMM package was used for the battery simulation. FIG. 1 illustrates the effect of the inputs on the response of the battery. According to the magnitude of the input, different voltages can be achieved for particular SOC. FIG. 5 shows the full discharge/charge curves, for two C-rates. One can use the information of the discharge/charge curve to calculate coulomb efficiency. Furthermore, the temperature can affect the battery's dynamic as shown in FIG. 6. FIG. 7 shows example results of the identified model. By incorporating the Kalman filter into the identified model, one can remove the noise from measured data and improve our model, as shown in FIG. 8. FIG. 9 displays the result of SOC prediction using only voltage and current.

In some embodiments, the method is flexible and allows for the addition of insights into the material, structure, and architecture of the batteries. Also, in some embodiments, it can be used to create models of individual cells in a battery pack or for module or pack levels.

Some benefits of using this system and model includes the following. First, it is non-invasive, non-destructive, and operando, so that the cells and modules can be in use while the estimation is performed. Second, it is fast and efficient, as there is no need to wait to generate lots of data from new battery technology, and there is no need to include specific information often proprietary to the battery manufacturers. Third, the testing and analysis can be done while the system is in operational mode with no required downtime. Fourth, the modeling technique is adaptive and allows for changing operating conditions and status of the batteries. Fifth, the method can be used in the presence of noise and disturbances. Sixth, the system and method do not require additional measurements beyond the ones typically used in battery management systems. Seventh, additional measurements and sensors can be accommodated easily to improve the modeling in any operating condition. Eighth, it can increase the safety of energy systems and the useful life of their energy storage devices as they can stay in service without fear of fire and other hazards due to over-charge or over-discharge.

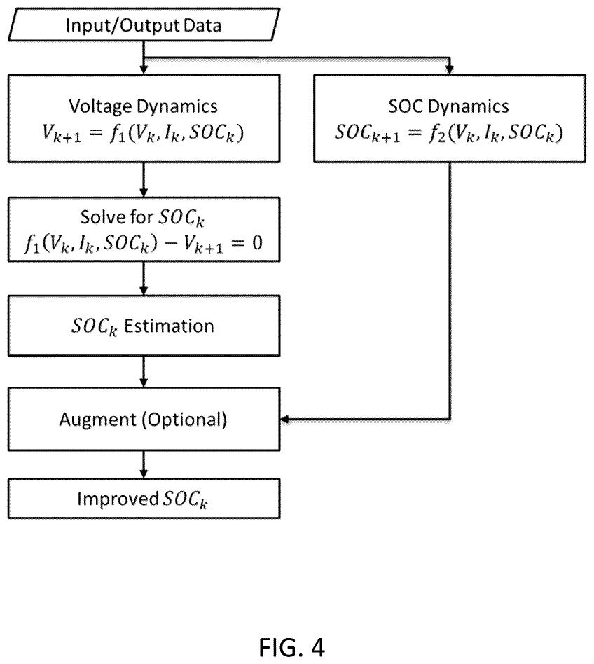

Referring now to FIGS. 1-4 exemplary battery SOC estimation methods, and systems are described. In some embodiments, a battery state-of-charge (SOC) estimation method 100 comprises applying an input 101 to the battery 102 comprising at least one of a voltage or a current. In some embodiments battery data is received from at least one sensor 103 associated with the battery, comprising a battery voltage, a battery current, and/or a battery temperature. In some embodiments, a calculation 104 is performed by applying a model 104 based on governing equations based on electrochemistry of the battery to the received battery data to perform a calculation (analysis) 106 to calculate the SOC, SOH, voltage, and/or temperature 107 of the battery.

In some embodiments, the model is continuously updated and learns over time. In some embodiments, the method is non-invasive and/or non-destructive. In some embodiments, the method is performed on a battery in its operating condition.

In some embodiments, the input is sinusoidal. In some embodiments, the model comprises a data-driven reduced order nonlinear model as detailed below. In some embodiments, as detailed below, the model is built via sparsification via sequentially thresholding ridge regression combined with a joint unscented Kalman filter. In some embodiments, the model is tuned via a cost function, as detailed below.

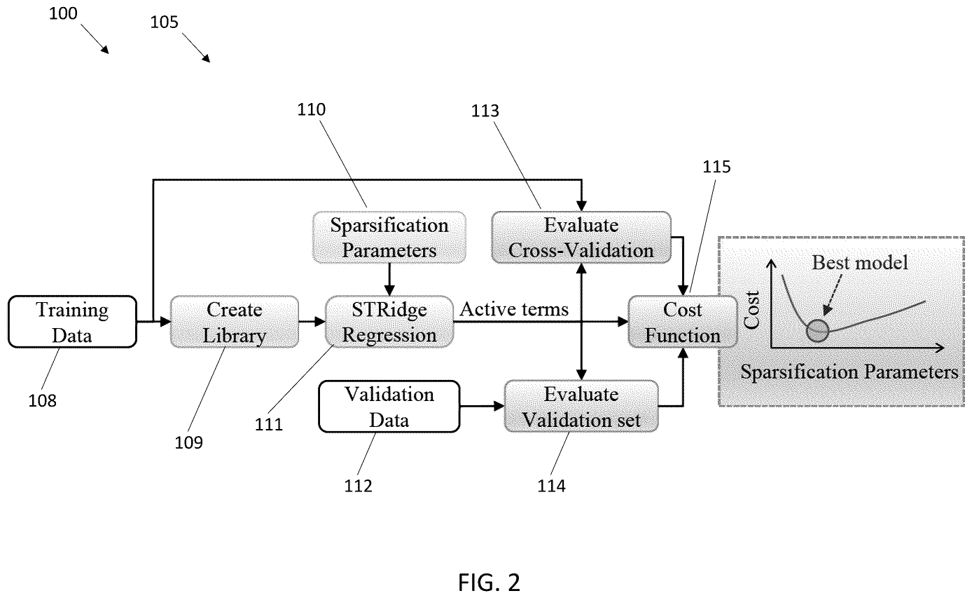

The model 105 is built as described in FIG. 2. Training data 108 is used to create a library 109. Sparsification parameters 110 are added to a regression 111 on the library 109. Validation data 112 and the training data 108 are used to evaluate a validation set 114 and cross-validation set 113, respectively, and a cost function 115 is then calculated to tune the sparsification parameters.

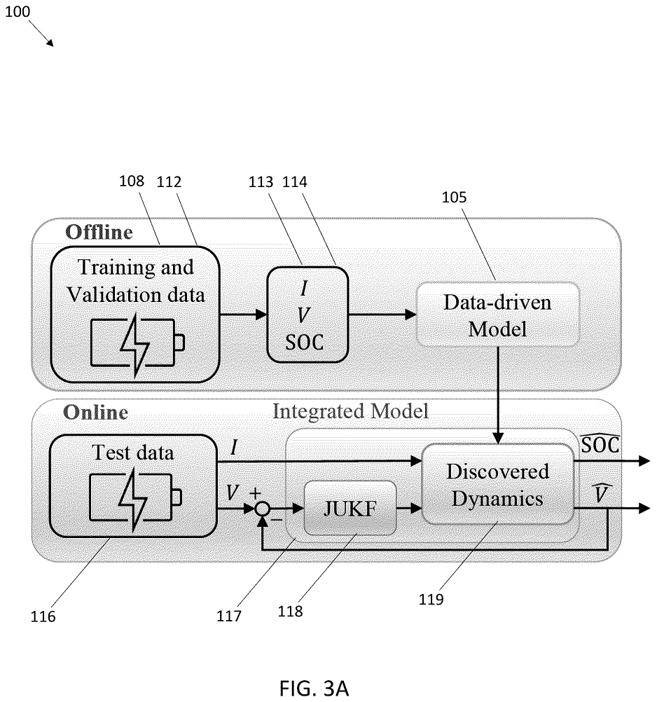

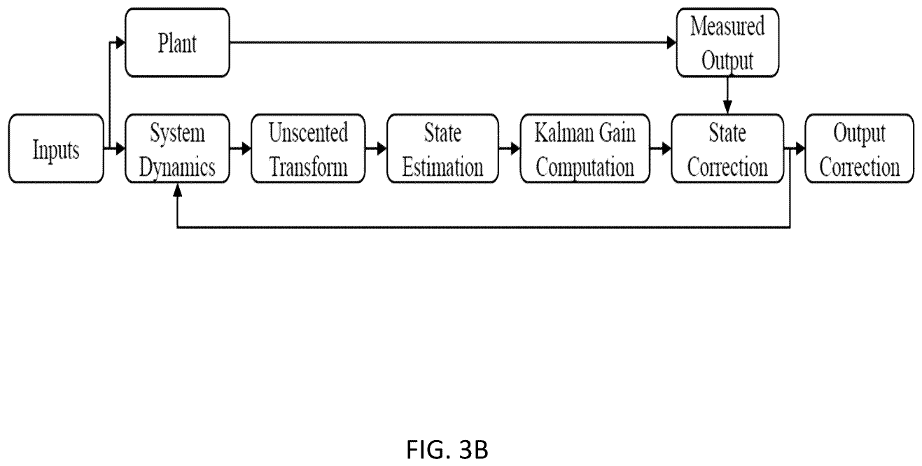

As shown in FIG. 3A, the data driven model 105 is built initially offline based on the training 108 and validation 112 data and validation 114, and cross-validation 113 sets. An integrated model 117 takes test data 116 and applies the base data driven model 105 with a joint unscented Kalman filter (JUKF) 118 to update the discovered battery dynamics 119 online to provide an estimated SOC of the battery.

In some embodiments, a battery SOC estimation system comprises at least one sensor associated with a battery, and a computing system communicatively connected to the at least one sensor, comprising a processor and a non-transitory computer-readable medium with instructions stored thereon, which when executed by the processor, performs the SOC estimation method as described above. In some embodiments, a non-transitory computer readable medium comprises program instructions for causing a computer to perform the SOC estimation method as described above.

Described below are further details of an interpretable data-driven model for discovering the governing equation of the system. Here, it's assumed that a general nonlinear dynamics of the following form can represent battery dynamics:

$$x [ k + 1 ] = f ( x [ k ] , u [ k ] ) \qquad ( 1 )$$

where x∈ [symbol] and u∈ [symbol] are the state and input variables, respectively, and f (x,u) is the unknown dynamics. Then, the aim is to find the appropriate (and as few as possible) functions of state and input variables that can approximate f (x,u). To achieve this goal, an extended sparsification algorithm [40] was used. The algorithm works by defining a library of potential terms Θ(x,u) such that x[k+1]=Θ(x[k],u[k])Ξ sparsifying their coefficients E.

The first step for generating the library is to collect m time snapshots of the state x and input u as shown below:

$$X ≡ X [ k , m ] ≡ {[ \begin{matrix}x [ k ] & x [ k + 1 ] & ⋯ & x [ k + m - 1 ]\end{matrix} ]}^{T} \qquad ( 2 )$$

$$U ≡ U [ k , m ] ≡ {[ \begin{matrix}u [ k ] & u [ k + 1 ] & ⋯ & u [ k + m - 1 ]\end{matrix} ]}^{T} \qquad ( 3 )$$

Next, a library of the potential terms is created. The aim is to determine the terms in the library that approximate the system dynamics Eq. (1) as follows:

$${X}^{′} = Θ ( X , U ) Ξ \qquad ( 4 )$$

where X′≡X[k+1,m] is a shifted temporal matrix of X, Θ(X, U)∈ [symbol] ^{m×d} is the candidate library, and Ξ∈ [symbol] ^{d×p} is a sparse vector of coefficients corresponding to elements of the library. The candidate library can be composed of linear and nonlinear functions to discover the unknown dynamics.

The model uses sequentially thresholded ridge regression (STRidge) optimization as a sparsification regression technique to compute the sparse vector of coefficients Ξ as follows:

$${Ξ}^{*} = arg {min}_{Ξ} ( {‖ {X}^{′} - Θ ( X , U ) Ξ ‖}_{2} + {ξ}_{t h} {‖ Ξ ‖}_{0} + λ {‖ Ξ ‖}_{2} ) \qquad ( 5 )$$

where sparsification parameters λ and ξₜₕ are the regularization and threshold parameters, respectively. These parameters are used to prevent overfitting by balancing accuracy and complexity. The regularization parameter, λ, is used to reduce the effect of non-dominant terms by reducing their coefficients Ξ. Then, the algorithm prunes the library by eliminating the unnecessary components with absolute values less than ξₜₕ. The algorithm is repeated until the convergence of the nonzero sparse coefficients. The STRidge algorithm is well-suited for handling correlated data, and battery dynamics are composed of PDEs that lead to highly correlated data (see S. H. Rudy, S. L. Brunton, J. L. Proctor, J. N. Kutz, Data-driven discovery of partial differential equations, Science advances 3 (4) (2017) e1602614) (see O. Ahmadzadeh, R. Rodriguez, D. Soudbakhsh, Modeling of li-ion batteries for real-time analysis and control: A data-driven approach, in: 2022 American Control Conference (ACC), IEEE, 2022, pp. 392-397). When λ=0, STRidge simplifies to sequentially thresholded least-squares (STLS), which is useful for discovering uncorrelated data.

A combination of sparsification parameters provides an optimal balance between accuracy and complexity, resulting in a more accurate model with fewer parameters. Here, the modified algorithm is used that treats the sparsification parameters, λ, and ξₜₕ as hyperparameters, and optimize them using training and validation datasets (see 0. Ahmadzadeh, R. Rodriguez, Y. Wang, D. Soudbakhsh, A physics inspired machine learning nonlinear model of li-ion batteries, in: 2023 American Control Conference (ACC), IEEE, 2023, pp. 3087-3092). Grid search methodology is employed to identify the optimal hyperparameters for STRidge regression. Training data is used to develop a model for all of the hyperparameters and formulate a cost function that is comprised of the root mean square error (RMSE) of training and validation data, along with the number of terms serving as a measure of model complexity. Subsequently, the hyperparameters are selected that yield the lowest cost function:

$$min . 𝒥 ( Ξ ) := {ρ}_{1} {RMSE}_{t} + {ρ}_{2} {RMSE}_{v} + {ρ}_{3} K \qquad ( 6 )$$

where ρ₁ and ρ₂ represent the penalties for modeling errors on the training and validation data, respectively. The number of nonzero terms in the sparse vector of coefficients, Ξ, is represented by K, with ρ₃ serving as a penalty for model complexity. Additionally, the RMSE is given by:

$$RMSE = \sqrt{\frac{1}{m + 1} {\sum }_{k = 1}^{m + 1} {( x [ k ] - \hat{x} [ k ] )}^{2}} \qquad ( 7 )$$

where \hat{x} is the predicted output from the model. FIG. 2 displays the methodology for selecting the hyperparameters.

This cost function offers an effective way of optimizing the model. It allows for a balance between the accuracy and complexity of the model while preserving the underlying data structure. A normalized coordinate was used for model identification to reduce the impact of scale differences among library elements on regression. Each element in the library was normalized by dividing it by its absolute maximum value. It is important to note that, to avoid having nonphysical errors in the modeling, the identified sparse vector of coefficients is regressed back to the actual coordinates.

### SOC Dynamics and Voltage Dynamics:

Described below is how the disclosed data-driven approach is used to generate a control oriented reduced-order model for LiBs. The battery's input is electrical current, I, and the outputs are voltage, V, and SOC. Therefore, the battery input-output model can be written as:

$$V [ k + 1 ] = Θ ( V [ k ] , SOC [ k ] , I [ k ] ) {Ξ}_{1} \qquad ( 8 )$$

$$SOC [ k + 1 ] = Θ ( V [ k ] , SOC [ k ] , I [ k ] ) {Ξ}_{2} \qquad ( 9 )$$

Although there is no constraint on selecting library terms, using generic functions (Polynomial) may hinder the model's accuracy in predicting output. To address this issue and to find the necessary coordinates to represent the reduced-order model for battery, the following terms are included in the library, Θ(V,SOC,I) based on the underlying dynamics of LiBs (see O. Ahmadzadeh, R. Rodriguez, Y. Wang, D. Soudbakhsh, A physics inspired machine learning nonlinear model of li-ion batteries, in: 2023 American Control Conference (ACC), IEEE, 2023, pp. 3087-3092), trigonometric terms (diffusion process), exponential terms (diffusion process), hyperbolic terms (Molar flux), and integral of current (SOC approximation).

Thus, the polynomial mixture of I, V, and SOC up to order two is included to account for other nonlinearities. Additionally, the double integral of the current is appended into the library to consider its evolution. The resultant library is given by:

$$Θ ( V , SOC , I ) = [ \begin{matrix}\vert & \vert & \vert & & \vert & \vert & \vert & \vert & \vert \\ V & {V}^{2} & VI & ⋯ & sin ( V ) & exp ( SOC ) & cos ( I ) & \int ( I ) & ⋯ \\ \vert & \vert & \vert & & \vert & \vert & \vert & \vert & \vert\end{matrix} ] \qquad ( 10 )$$

where each column represents a time-series data of the candidate term.

### Joint Unscented Kalman Filter:

The Kalman filter framework is comprised of prediction and correction steps. The prediction step estimates the state and uncertainty of the current state based on past observations. The correction step updates the state and uncertainty based on new observations. The unscented Kalman filter (UKF) utilizes the Kalman filter framework for nonlinear systems such as Li-ion battery dynamics instead of traditional methods like the extended Kalman filter algorithm that linearizes the nonlinear system (see E. A. Wan, R. Van Der Merwe, The unscented Kalman filter for nonlinear estimation, in: Proceedings of the IEEE 2000 Adaptive Systems for Signal Processing, Communications, and Control Symposium (Cat. No. 00EX373), Ieee, 2000, pp. 153-158).

The discrete systems have two possible uncertainties: i) uncertainty in the system's parameter and ii) uncertainty in the state dynamics. Integrating the Joint UKF (JUKF) helps address uncertainty in both the nonlinear states and parameters concurrently, enhancing the algorithm's robustness. Let us consider a discrete nonlinear dynamical system with stationary dynamics for the parameter n:

$$n [ k + 1 ] = n [ k ] + {w}_{1} [ k ] \qquad ( 11 )$$

$$x [ k + 1 ] = f ( x , {w}_{2} [ k ] ; n [ k ] ) \qquad ( 12 )$$

$$y [ k ] = h ( x [ k ] , v [ k ] ; n [ k ] ) \qquad ( 13 )$$

where w₁[k] and w₂[k] are the process noises, which are assumed to be Gaussian white noise, x[k] and y[k] represent the state and output in the k time step, respectively, and v[k] is the zero mean measurement noise with covariance R. Nothing of the system dynamics f and h are known.

To estimate both states and parameters simultaneously, these variables are combined into a unified joint state vector z=[x^{T} n^{T}]^{T}. The state-space equations can be represented more concisely and conveniently using this joint state vector as follows:

$$z [ k + 1 ] = F ( z [ k ] ) + w [ k ] \qquad ( 14 )$$

$$y [ k ] = H ( z [ k ] ) + v [ k ] \qquad ( 15 )$$

where

$$w = {[ \begin{matrix}{w}_{2}^{T} & {w}_{1}^{T}\end{matrix} ]}^{T}$$

with Q covariance, and H(z[k])=[1 0]z[k]. The initial values for the augmented state 2 and covariance P_{z} to are used to initialize the filter. Employing the unscented transform, the method utilizes 2L+1 sigma points Xᵢ to capture statistics of y in the following manner:

$$𝒳 [ k - 1 ] = [ \begin{matrix}\hat{z} [ k - 1 ] & \hat{z} [ k - 1 ] + \sqrt{( L + γ ) {P}_{z}} & \hat{z} [ k - 1 ] - \sqrt{( L + γ ) {P}_{z}}\end{matrix} ] \qquad ( 16 )$$

where γ=α²(L+κ)−L is a scaling parameter, a controls the spread of sigma points around \hat{z}, and is commonly assigned to small value such as 10⁻³ (see E. A. Wan, R. Van Der Merwe, The unscented Kalman filter for nonlinear estimation, in: Proceedings of the IEEE 2000 Adaptive Systems for Signal Processing, Communications, and Control Symposium (Cat. No. 00EX373), Ieee, 2000, pp. 153-158). The constant K is the second scaling parameter and is typically set to 3−L (see E. A. Wan, R. Van Der Merwe, The unscented Kalman filter, Kalman filtering and neural networks (2001) 221-280).

The sigma points are generated using the nonlinear state function in the following manner:

$${𝒳}_{i}^{-} [ k ] = F ( {𝒳}_{i} [ k - 1 ] ) \qquad ( 17 )$$

Now, one can determine the prior estimate of the state \hat{z}−[k] and the corresponding error covariance matrix

$${P}_{z}^{-} [ k ]$$

as follows:

$${\hat{z}}^{-} [ k ] = {\sum }_{i = 0}^{2 L} {W}_{i}^{( m )} {𝒳}_{i}^{-} [ k ] \qquad ( 18 )$$

$${P}_{z}^{-} [ k ] = {\sum }_{i = 0}^{2 L} {W}_{i}^{( c )} ( {𝒳}_{i}^{-} [ k ] - {\hat{z}}^{-} [ k ] ) {( {𝒳}_{i}^{-} [ k ] - {\hat{z}}^{-} [ k ] )}^{T} + Q \qquad ( 19 )$$

where factors

$${W}_{i}^{( m )} and {W}_{i}^{( c )}$$

serve as the weighting coefficients and are expressed as:

$${W}_{0}^{( m )} = \frac{γ}{L + γ} \qquad ( 20 )$$

$${W}_{0}^{( c )} = \frac{γ}{L + γ} + 1 - {ξ}_{th}^{2} + β \qquad ( 21 )$$

$${W}_{i}^{( m )} = {W}_{i}^{( c )} = \frac{1}{2 ( L + γ )} , i = 1 , … , 2 L + 1 \qquad ( 22 )$$

where β integrates prior information about the state distribution and optimally is 2 for Gaussian distribution (see E. A. Wan, R. Van Der Merwe, The unscented Kalman filter for nonlinear estimation, in: Proceedings of the IEEE 2000 Adaptive Systems for Signal Processing, Communications, and Control Symposium (Cat. No. 00EX373), IEEE, 2000, pp. 153-158).

The propagated sigma points of Eq. (17) are utilized for generating the measurement sigma points:

$${𝒴}_{i}^{-} [ k ] = H ( {𝒳}_{i}^{-} [ k ] ) . \qquad ( 23 )$$

Through the utilization of the weighting factor, a priory measurement estimate is determined as follows:

$${\hat{y}}^{-} [ k ] = {\sum }_{i = 0}^{2 L} {W}_{i}^{( m )} {𝒴}_{i}^{-} [ k ] . \qquad ( 24 )$$

Now, one can compute the measurement and cross-covariances, respectively, in the following manner:

$${P}_{y} [ k ] = {\sum }_{i = 0}^{2 L} {W}_{i}^{( c )} ( {𝒴}_{i}^{-} [ k ] - {\hat{y}}^{-} [ k ] ) {( {𝒴}_{i}^{-} [ k ] - {\hat{y}}^{-} [ k ] )}^{T} + R \qquad ( 25 )$$

$${P}_{zy} [ k ] = {\sum }_{i = 0}^{2 L} {W}_{i}^{( c )} ( {𝒳}_{i}^{-} [ k ] - {\hat{z}}^{-} [ k ] ) {( {𝒴}_{i}^{-} [ k ] - {\hat{z}}^{-} [ k ] )}^{T} \qquad ( 26 )$$

The Kalman gain matrix for correction is carried out as follows:

$$𝒦 [ k ] = {P}_{zy} [ k ] {P}_{y}^{- 1} [ k ] . \qquad ( 27 )$$

Following the computation of the Kalman gain filter, the posterior state estimate is determined as follows:

$$\hat{z} [ k ] = {\hat{z}}^{-} [ k ] + 𝒦 [ k ] ( y [ k ] - {\hat{y}}^{-} [ k ] ) \qquad ( 28 )$$

Ultimately, the correction of the estimation error covariance is performed as follows:

$${P}_{z} [ k ] = {P}_{z}^{-} [ k ] - 𝒦 [ k ] {P}_{y} [ k ] {𝒦}^{T} [ k ] \qquad ( 29 )$$

FIG. 3B displays the UKF framework for updating the state and correcting measurement using the unscented transformation for estimating the state.

### Integrated SOC and Voltage Estimator:

Here, the identified nonlinear reduced-order model Eqs. (8)-(9) is augmented with the JUKF to enhance the estimation and mitigate the effect of noise. The nonlinear reduced-order model, similar to other governing dynamics discovered through the SINDy algorithm, does not incorporate information from the output/observer. The only information this model requires is the initial value of the state, where the wrong initial state can lead to inaccurate predictions.

In addition, for the present model, the voltage data is easily measurable, however, it is noisy. Consequently, this noise can deteriorate the accuracy of the identified model as it depends on the data quality. This noise is treated as uncertainties wᵥ and w_{Ξ} in the discovered dynamics for voltage Eq. (8) and in the sparse vector of coefficients corresponding to the voltage dynamics, respectively. In contrast, the SOC is not readily measurable. Therefore, the estimated SOC can be inaccurate and needs to be constantly updated, and this inaccuracy will introduce uncertainty wₛ to SOC dynamics Eq. (9). To address these, the JUKF is incorporated into the model to mitigate the effect of noise from measured voltage data and converge the estimated SOC with inaccurate initial conditions to the estimated SOC with the correct initial value. FIG. 3A displays the disclosed model with JUKF where V and [symbol] are the predicted output. The nonlinear reduced-order model with uncertainty is formulated as follows:

$${Ξ}_{r , 1} [ k + 1 ] = {Ξ}_{r , 1} [ k ] + {w}_{Ξ} [ k ] \qquad ( 30 )$$

$$V [ k + 1 ] = {θ}_{r , 1} [ k ] {Ξ}_{r , 1} [ k ] + {w}_{V} [ k ] \qquad ( 31 )$$

$$SOC [ k + 1 ] = {θ}_{r , 2} [ k ] {Ξ}_{r , 2} [ k ] + {w}_{S} [ k ] \qquad ( 32 )$$

$${V}_{o} [ k ] = V [ k ] + {v}_{V} [ k ] \qquad ( 33 )$$

where Ξ_{r,1} and Ξ_{r,2} are the nonzero terms of the sparse vector of coefficients for voltage Ξ₁ and SOC Ξ₂, respectively. Additionally, θ_{r,1}[k] and θ_{r,2}[k] refer to the terms in the k^{th} row of Θ(V,SOC,I) corresponding to the Ξ_{r,1} and Ξ_{r,2}, respectively; v[k] is the measurement noise, and Vₒ is the noisy measured voltage.

Similar to above, the augmented state z=[V SOC Ξ_{r,1}]^{T} is introduced for utilization in the JUKF, and measured voltage data Vₒ serves as the model output. The JUKF updates the state z to estimate the nonzero sparse coefficients for voltage, SOC dynamics, and voltage dynamics based on the measured voltage data. Consequently, the estimated SOC with an incorrect initial value converges to the estimated SOC with the correct initial value. Simultaneously, the voltage data is refined by mitigating the effect of measurement noise. Although, in practical applications, the electrical current is noisy too, the calculations account for this by considering the effect of electrical current noise as process noise.

### EXPERIMENTAL EXAMPLES

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore specifically point out exemplary embodiments of the present invention, and are not to be construed as limiting in any way the remainder of the disclosure.

To showcase the high accuracy and robustness of the proposed model, experiments were using various electrical current profiles. The results indicate the model's robustness and high accuracy compared to commonly used ECM with extended Kalman filter (EKF). Moreover, the interpretable model is computationally affordable and can predict the SOC and refine voltage in real-time, and its parameters can be updated during the battery's lifespan.

A 21700 cylindrical lithium-ion cell with a graphite anode and NCM811 (Nickel-Manganese-Cobalt) cathode was used for experimentation. The cell had a nominal capacity of 4.8 Ah. During the experiments, the charge and discharge cutoff voltages were set at 4.2 volts and 2.5 volts according to manufacturer recommendations, respectively. The C-rate refers to the rate of charge/discharge compared to the battery's capacity. The cell allowed a maximum continuous charging current of 1.44 A (0.3 C-rate) with a 50 mA charge cutoff current. All experiments were conducted at a temperature of 25° C. within a controlled thermal test chamber.

First, the battery was cycled three times with the constant current constant voltage (CCCV) method with a 0.3 C-rate to a maximum voltage of 4.2 V and a discharge rate of 1 C to a minimum voltage of 2.5 V.

After cycling the battery, it was fully charged using the CCCV method, followed by two hours of rest. The cell was subjected to a custom drive cycle electrical current profile designed for this study. When the voltage reached the 2.5 V limit, the cell underwent a complete discharge using the Constant Voltage (CV) method. The electrical current for the custom drive cycles was set to 5 A for charge and 8.5 A for discharge, which accounts for simulating aggressive driving conditions and covers the entire permissible voltage range of the battery.

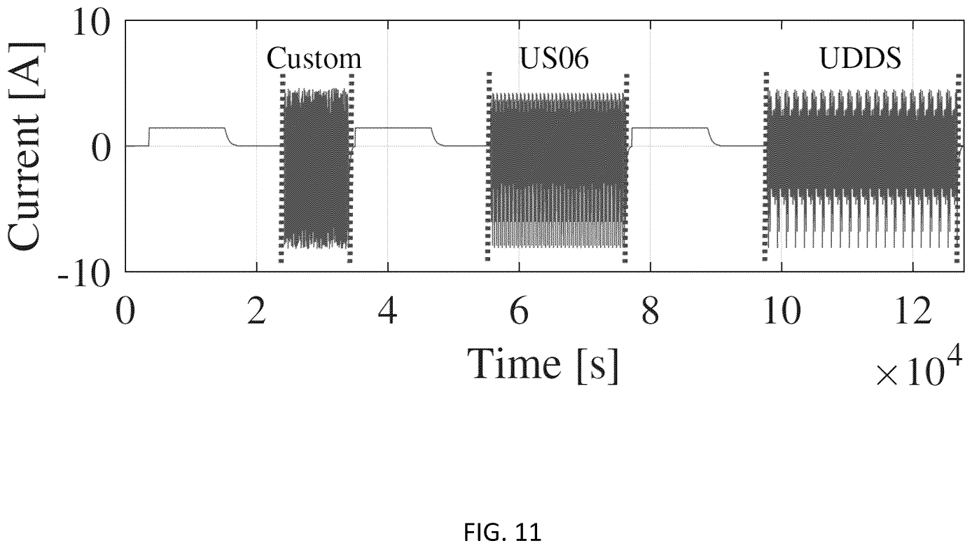

The data from the custom drive cycle was used as the training data to create the reduced-order model using Eq. (5). A similar procedure was followed for employing current profiles of the US-highway (US06) and Urban Dynamometer Driving Schedule (UDDS) drive cycles (see J. M. Reniers, G. Mulder, D. A. Howey, Review and performance comparison of mechanical-chemical degradation models for lithium-ion batteries, Journal of The Electrochemical Society 166 (14) (2019) A3189) (see OAR. US EPA, Dynamometer Drive Schedules, https://www.epa.gov/vehicle-and-fuel-emissions-testing/dynamometerdrive-schedules (September 2015)). The US06 and UDDS current profiles were repeated until the cell reached the voltage limit of 2.5 V. The US06 drive cycles represent aggressive vehicle driving at high speeds, while the UDDS simulates driving in a city environment. The data obtained from the US06 profile served as the validation dataset for tuning sparsification parameters using the proposed cost function Eq. (6). The collected data from the UDDS profile was utilized as the test dataset to evaluate the model's generalizability. FIG. 11 displays the custom, US06, and UDDS current profiles used for generating data, followed by charging and rest time. The sampling time for the experiment is set to 50 ms (see R. Rodriguez, O. Ahmadzadeh, Y. Wang, D. Soudbakhsh, Discovering Governing Equations of Li-ion Batteries Pertaining State of Charge Using Input-Output Data, in: ACC'2023, San Diego, CA, USA, 2023).

The SOC of commercial cells cannot be measured directly. Therefore, SOC was estimated using the enhanced coulomb counting approach. The measured charge and discharge capacity were utilized to calculate the coulomb efficacy, allowing a more accurate estimation of the battery's SOC. With this approach, it was possible to estimate the SOC of our cell during the experiment accurately.

### Sparsification Parameters Optimization Results:

To start the optimal sparsification parameters (threshold th and regularization A) were found using the cost function in Eq. (6) for both SOC and voltage dynamics. In discovering the governing equation for SOC, voltage data is known, and similarly, SOC data is known in discovering governing equations for voltage. ρ₁=ρ₂=100 and ρ₃=0.1 were selected for example values in the cost function. Equal weights were assigned to the training and validation RMSE to ensure a fair assessment of the model's performance. Note that a cross-validation procedure (using only the initial value to predict the time series data) was used to assess the RMSE of training data. The weight of the sparsity component is also modified to accommodate the scale difference between the RMSE and sparsity components. This enables one to discover governing equations that balance sparsity and accuracy for both voltage and SOC.

A grid search approach of 10⁻⁸ to 1 was used to find the optimal sparsification parameters that minimize the cost function. After selecting the terms to include in the library of potential terms Θ, training data was used to create a reduced order model for each set of sparsification parameters using STRidge regression in Eq. (5). The validation error of each model was computed, and the number of terms used in each model was determined. Utilizing the training and validation error and the number of terms, the cost function was calculated for each set of sparsification parameters. The sparsification parameters with the minimum cost were then used to create the final reduced-order model.

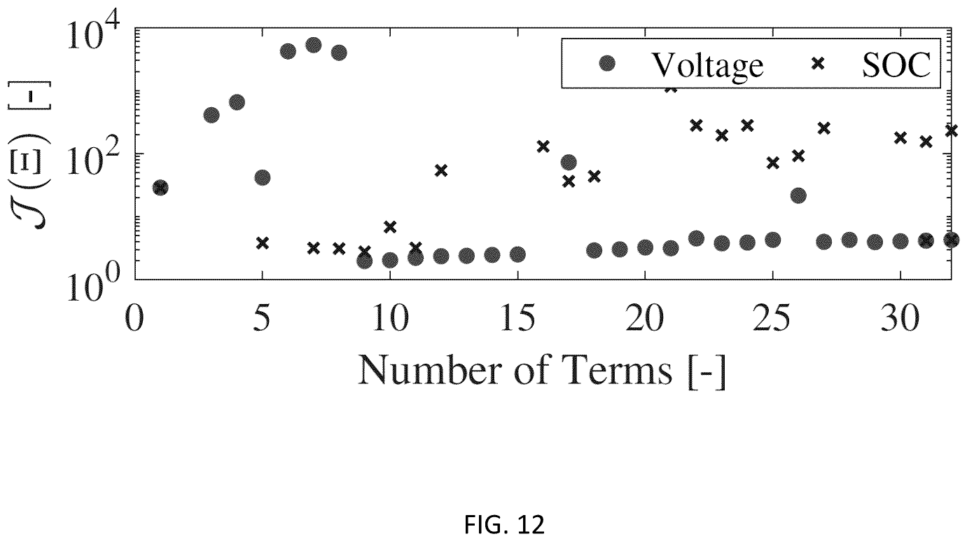

To visualize the effect of the cost function on model complexity, FIG. 12 illustrates the cost function against the number of nonzero terms for both voltage and SOC, where nine terms are enough for estimating SOC and Voltage. Only the model with the lowest cost function is displayed for each number of terms, as different sparsification parameters can have the same number of nonzero terms with different costs. The sparsification parameters' values adjust the model's complexity by influencing the number of active terms in the sparse vector of coefficients. Employing small values of sparsification parameters introduces additional terms into the model; however, these terms may overfit the training data. Moreover, relying only on accuracy may yield an accurate model which is not sparse. For instance, regarding the voltage prediction, using 15 terms results in the lowest validation error (RMSE of 0.0078); however, many of these terms are redundant, contributing to increased model complexity. Consequently, 9 terms were opted for to yield a validation RMSE of 0.0086 using the above cost function. Thus, the cost function helps one identify less useful terms and remove them from the model, resulting in a more interpretable and sparser model.

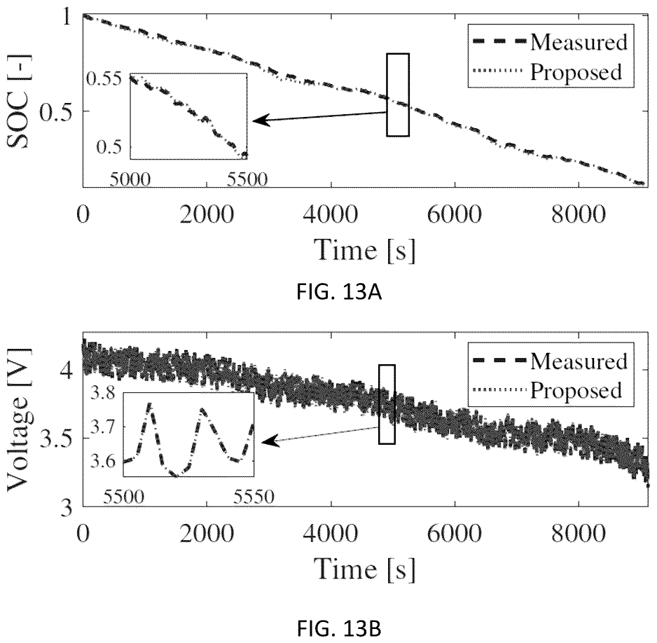

The training data was used to construct the model using the optimal sparsification parameters. Shown in FIGS. 13A-13B are the SOC and voltage cross-validation results obtained from the training data, respectively. The results demonstrate that the discovered governing equations for voltage and SOC are accurate for the highly aggressive custom data. The model can identify and predict the voltage and SOC in real-time accurately. This enables one to build a reliable predictive model for an electric vehicle system.

### SOC Estimation and Voltage Correction Results:

Using the appropriate Q and R parameters for JUKF, the voltage data was corrected mitigating the noise effect and ensuring convergence of the SOC to its correct value concurrently. The model with JUKF outperforms the traditional SINDy model as it updates the parameters and states using the measured voltage data information.

In addition, the commonly used technique ECM with EKF was selected to compare the accuracy of the disclosed method. ECM parameters were tuned using the training data and EKF parameters were tuned with validation data. The model was then tested on the unseen test data and the results were compared with the ECM with EKF method. The results showed that the disclosed method significantly outperformed the ECM with EKF.

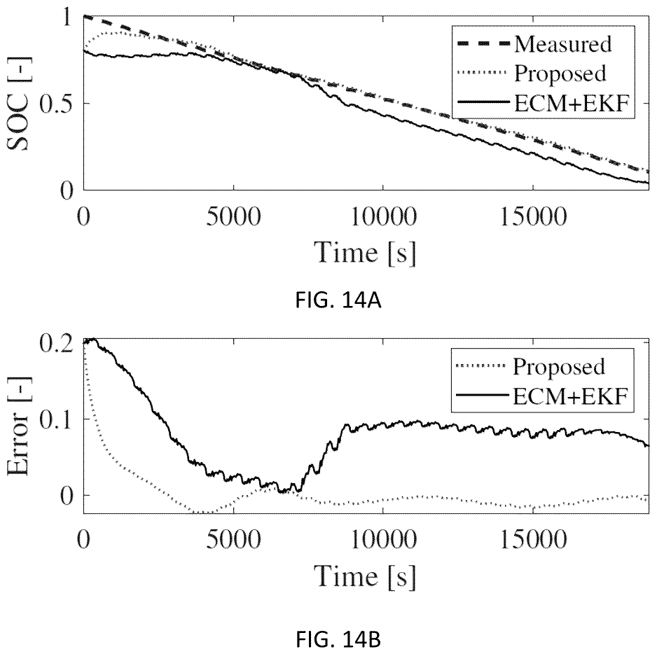

FIG. 14A illustrates the SOC estimation for the validation data. The identified model simultaneously estimates the SOC and voltage using the electrical current profile. The initial value of the SOC is set at 1 (fully charged). However, 0.8 SOC (20% uncertainty) was used as the initial value for SOC estimation. FIG. 14B displays the SOC estimation error for the validation data. The disclosed model converges toward the actual SOC compared to the ECM with EKF, showcasing the robustness of the disclosed model approach. The SOC validation RMSE of the model after convergence was 0.0102, highlighting its high accuracy.

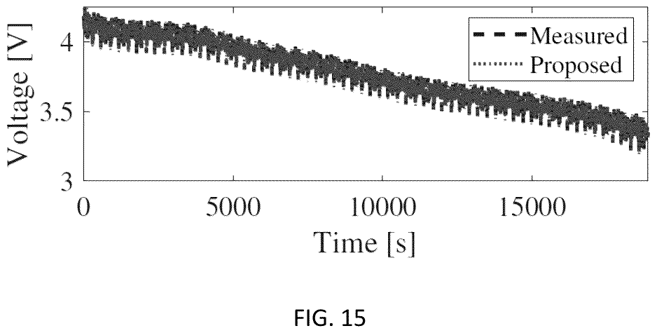

FIG. 15 presents the voltage correction result under the US06 validation data. The JUKF effectively handles model uncertainties, achieving an RMSE of 0.0008 V. As can be observed, the uncertainty in SOC does not affect the performance of the proposed model for correcting the voltage data.

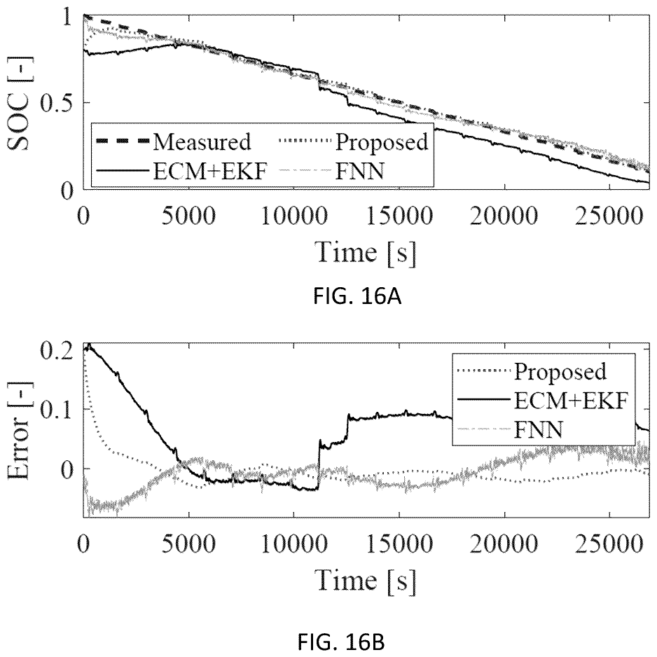

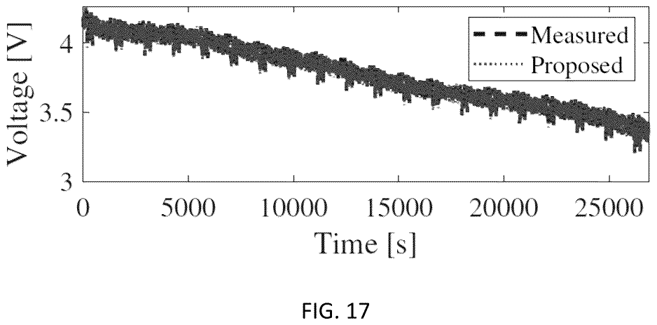

The model's performance was further tested on the unseen UDDS test data set. FIGS. 16A-16B and FIG. 17 display the SOC estimation and voltage correction results, respectively. Similar to the validation dataset, a 20% uncertainty was considered in the SOC initial value. As can be observed in FIG. 16B, the disclosed model converges to the actual SOC. However, the ECM with EKF converges slowly and tends to diverge around 50% SOC, maintaining a stable overall error. In addition, the model has an RMSE of 0.0130 after convergence, highlighting the model's generalizability in unseen scenarios. Furthermore, the model achieves an RMSE of 0.0006 V for correcting UDDS voltage data.

The RMSE and mean absolute error (MAE) for SOC prediction after convergence and voltage correction for US06 validation and UDDS test data are given in Table 1 below. The Maccor model 4200 battery tester was used with a ±0.02% full-scale range (FSR) voltage accuracy. Hence, the experiment's voltage measurement accuracy is approximately ±0.0004 V, in close agreement with the achieved MAE from the disclosed model. The results indicated that the discovered governing equations are robust and can be used confidently.

TABLE 1
SOC estimation after convergence and voltage correction results:

| | | RMSE | MAE |
|---|---|---|---|
| US06 | SOC | 0.0102 | 0.0085 |
| | Voltage | 0.0008 V | 0.0005 V |
| UDDS | SOC | 0.0130 | 0.0108 |
| | Voltage | 0.0006 V | 0.0004 V |

### Evaluation on Different Temperature States

The performance of the model was then evaluated under varying operating conditions. The experiments described above were repeated at temperatures of 10° C. and 40° C. to verify the model's accuracy. The model identified at 25° C. is used as the baseline, meaning only the coefficients of the governing equations were updated, which contain 9 terms each for both voltage and SOC, as shown in FIG. 12. In this scenario, the coefficients are updated using the least squares error method rather than STRidge since the governing equation is already known from the 25° C. data.

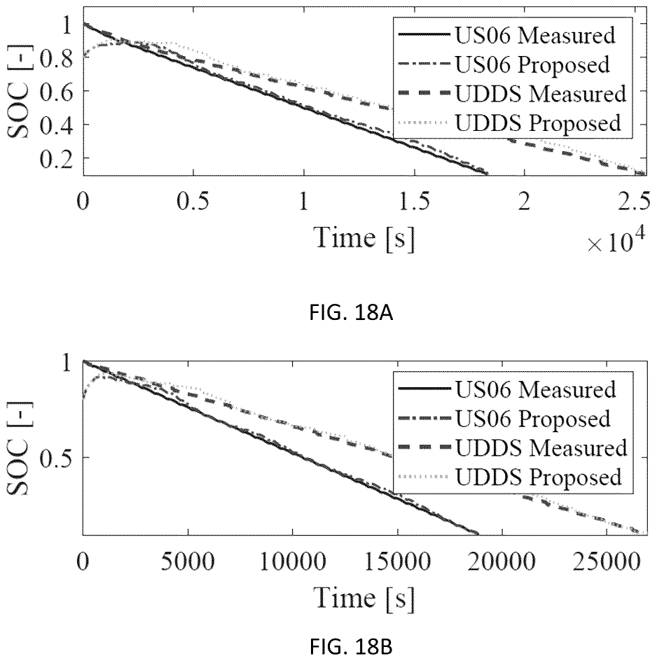

At 10° C., the model achieved an RMSE of 0.0062V for voltage prediction and 0.0061 for SOC prediction using the training data. Additionally, when tested with a 20% error in the initial SOC value, the model attained an RMSE of 0.0283 for SOC estimation after convergence and an RMSE of 0.0026 V for voltage correction during the US06 drive cycle. Finally, the model's performance was evaluated using UDDS data, starting with an 80% initial SOC (representing a 20% error). The model successfully converged to the actual SOC value with an RMSE of 0.0325 after convergence and an RMSE of 0.0019 V for voltage correction. FIG. 18A displays the SOC convergence for both US06 and UDDS data with 20% error in initial value at 10° C. It is worth noting that at lower temperatures, the battery's internal resistance increases. To prevent the voltage from exceeding the cell limit, the charging current (regenerative) was reduced at the beginning of the cycles.

A similar approach was followed for 40° C., where cross validation of training data yielded an RMSE of 0.0083 for SOC prediction and 0.0021 V for voltage prediction when adjusting the coefficients. For the US06 drive cycle, the SOC with an initial error of 20% converged to its true value with an RMSE of 0.0144 after convergence, as shown in FIG. 18B. The JUKF effectively mitigated the impact of measurement noise, achieving an RMSE of 0.0006 V for the voltage data. FIG. 18B shows the model's accuracy in correcting the SOC with a 20% initial error for UDDS data, also resulting in an RMSE of 0.0158 after convergence. Furthermore, the model achieves an RMSE of 0.0005 V in voltage correction for UDDS data, illustrating the robustness of JUKF in handling noise.

These results demonstrate the model's generalizability and applicability across different operating conditions. Only the coefficients of the governing equation identified at 25° C. were updated using training data at different temperatures, proving that the underlying dynamics were correctly captured at 25° C. The same methodology can be extended to other temperatures or battery health states, showcasing the transferability of the method.

### Discussion and Conclusions:

A data-driven approach has been described to co-estimate SOC and Voltage values and their dynamics. The algorithm works in two steps: 1) Discovering the battery's governing equations pertaining to SOC and voltage dynamics and 2) using a joint co-estimation to remove noise from the voltage and estimate the correct SOC values.

The SOC dynamics in step 1 can accurately predict the SOC dynamics; however, it requires the correct initial values. Otherwise, its performance degrades and makes it unattractive for practical applications. A common method for estimating initial values of SOC is using SOC-OCV maps, which require a significant amount of training data from a control group of batteries. Cell-to-cell variations and changes in the cells limit the accuracy of SOC-OCV mappings, and their performance degrades over time. The second equation pertaining to voltage dynamics offers a solution to this problem by learning such mapping by determining a nonlinear relation between the terminal voltage and SOC values. Note that the algorithm described herein can be implemented online. While the entire algorithm, from forming the appropriate library to finding the coefficient, is an offline process, once the algorithm finds an appropriate set of reduced (sparsed) library terms, the only unknowns are the coefficients of these terms. The vector of the coefficients will be updated by the JUKF algorithm as the battery ages or its operating conditions change. Therefore, this terminal voltage-SOC mapping can be updated in real-time using terminal voltage instead of OCV and adapts to the new conditions of the batteries.

The second contribution is the complete determination of the correct SOC values using the data. This part was achieved through adjoining voltage and SOC dynamics for a co-estimation of the coefficients as well as the SOC values. Further it was shown that the SOC converges to its correct values through experimental studies. The disclosed method can be integrated into the battery management system (BMS) to correct voltage and estimate SOC concurrently. The model requires less data for training than other machine learning algorithms, and due to its simplicity, it can be implemented in BMS. In addition, accurate SOC estimation is crucial for precise state of power (SOP) estimation in batteries, as it indicates the available energy within the battery, ensuring efficient and safe battery operation.

The other significant contribution of this study is the disclosed sparse identification algorithm that can be applied to any other system subject to the assumptions in Ng et al. (see K. S. Ng, C.-S. Moo, Y.-P. Chen, and Y.-C. Hsieh, “Enhanced coulomb counting method for estimating state-of-charge and state-of-health of lithium-ion batteries,” Applied Energy, vol. 86, no. 9, pp. 1506-1511, 2009). Integrating the joint unscented Kalman filter to join different dynamics for an improved closed-loop model resulted in an adaptive modeling technique and filtering out of the measurement noise in voltage. The accuracy of the method in determining the SOC dynamics was shown, and the steady-state RMSE error was 0.013. This was achieved by replacing the common approach in obtaining the sparse nonlinear dynamics using an AIC inspired cost function with a new cost function. Note that using the AIC-inspired cost function resulted in only one term (compared to 9 terms previously), and the RMSE of the test data was significantly higher (RMSE≈0.3). These results point to a limitation of the AIC-inspired cost function as it tries to estimate the model's prediction error using only “in-sample” errors. While such a cost function is effective in some scenarios, it does not yield an acceptable generalizable error (test data) for the complex dynamics of Li-ion batteries. On the other hand, the disclosed formulation resembles the cross-validation method as it uses “extra-sample” (validation data) to balance the model's complexity and accuracy. As a result, the model is more generalizable (smaller test errors) when tested using simulation studies or experimental battery data.

Also presented was a methodological approach for picking the initial library terms using domain knowledge. While the exact analytical solutions of the battery dynamics are not tractable, their solution form provided a guideline to create the library terms. The process of identifying library terms and their coefficients was conducted offline; however, the coefficients can be adapted online. This adaptability enables the model to perform well under various operating conditions by updating the SOC-voltage map. Moreover, the proposed approach can be applied to other complex dynamical systems to construct a reduced-order model. It can provide insight into the system's dynamic behavior, aiding in system control or optimization. Overall, the proposed approach is an effective and efficient way to create a reduced-order model and gain valuable insights into the system's behavior.

The disclosed systems and methods can be integrated into the battery management system (BMS) to correct voltage and estimate SOC concurrently. The model requires less data compared to other machine learning algorithms for training, and due to its simplicity, it can be used to estimate SOC and correct voltage data in real time. Another advantage of the disclosed model is its capability to converge to the actual SOC even when initialized with inaccurate values.

The SINDy algorithm was enhanced by integrating the JUKF to create a robust model that manages noise and uncertainties in dynamics. The model utilized the available voltage data to continuously update its parameters and dynamics. Furthermore, employing the STRidge regression identified active terms effectively. On the other hand, using the STLS (λ=0) resulted in poor performance for both SOC and voltage, as it is not suitable for identifying PDEs present in battery dynamics.

Furthermore, including the validation error in the cost function for selecting sparsification parameters improved the model's generalizability. Akaike information criterion (AIC)-inspired cost function (see N. M. Mangan, J. N. Kutz, S. L. Brunton, J. L. Proctor, Model selection for dynamical systems via sparse regression and information criteria, Proceedings of the Royal Society A: Mathematical, Physical and Engineering Sciences 473 (2204) (2017) 20170009) is commonly employed to tune the sparsification parameters. The AIC-inspired cost function relies only on training error and sparsity, resulting in a model with only one term (Integral of current from enhanced coulomb counting) for SOC estimation. While the model is highly sparse, it performs poorly with US06 and UDDS data. Therefore, the AIC-inspired cost function is not a generalizable approach to tuning sparsification parameters. In contrast, it was demonstrated that the addition of the validation error to the cost function resulted in a more generalizable model, as displayed in Table 1.

The process of identifying library terms and their coefficients is conducted offline; however, the coefficients can be adapted online. This adaptability enables the model to perform well under various operating conditions. Moreover, the disclosed approach can be applied to other complex dynamical systems to construct a reduced-order model. It can provide insight into the dynamic behavior of the system, aiding in system control or optimization. Overall, the proposed approach is an effective and efficient way to create a reduced-order model and gain useful insights into the system's behavior.

As described above a reduced-order data-driven model was disclosed for discovering the governing equations of SOC and voltage. The disclosed model predicts the SOC and voltage using the electrical current as the input. the SINDyC algorithm was enhanced by integrating the validation data into a novel cost function to tune sparsification parameters. Unlike most of the SINDyC algorithms that utilized generic terms to build a library of potential terms, terms were included based on the electrochemistry of the battery, providing the necessary representation of the battery's dynamics.

The experiment on 21700 cylindrical cells with NCM811 cathode material at 25° C. was conducted to collect data. The stochastic electrical current associated with aggressive custom driving served as training data. The electrical current representing the highway driving cycle (US06) and urban driving cycle (UDDS) were utilized to generate validation and test datasets, respectively. The training and validation data were employed to tune sparsification parameters, while the test data evaluated the model's generalizability.

Estimation of SOC is challenging, especially when the initial value is unknown. The SINDyC algorithm relies on accurate information about the SOC initial value to predict time series SOC. Moreover, the SINDyC algorithm does not incorporate measurement information to update its dynamics. In the disclosed model, SOC and voltage are states, and the JUKF was used to jointly estimate the SOC and voltage, as well as a sparse vector of coefficients corresponding to the voltage dynamics, using the measured noisy voltage data. This enables one to mitigate noise effects from the model. Similar to other data-driven algorithms, noise can deteriorate the model performance; therefore, augmenting SINDyC with JUKF improved its performance by correcting the voltage data and using the corrected voltage data in SOC dynamics. In addition, JUKF utilized the measured voltage data to reduce the uncertainty in SOC dynamics, especially due to inaccurate SOC initial values. It created a model that updates state and parameters dynamically with the measured data. This improved the accuracy of the model and enabled it to predict SOC with higher accuracy.

In conclusion, this approach provides a robust and accurate tool for real-time SOC estimation and voltage correction. The experimental results on unseen UDDS test data demonstrated that the model achieved an RMSE of 0.0130 for SOC estimation after convergence and an RMSE of 0.0004 V for correcting voltage. Furthermore, the disclosed model converged to the actual SOC more rapidly compared to the ECM with EKF, which started to diverge after the SOC dropped to 50%. The model's performance proved promising and could be used in real-world applications. Moreover, this technique needs less data than other machine learning methods, such as neural networks. Therefore, the model can be trained quickly while the battery's dynamics change due to aging or environmental conditions.

### Computing Environment

In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, JavaScript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth©, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

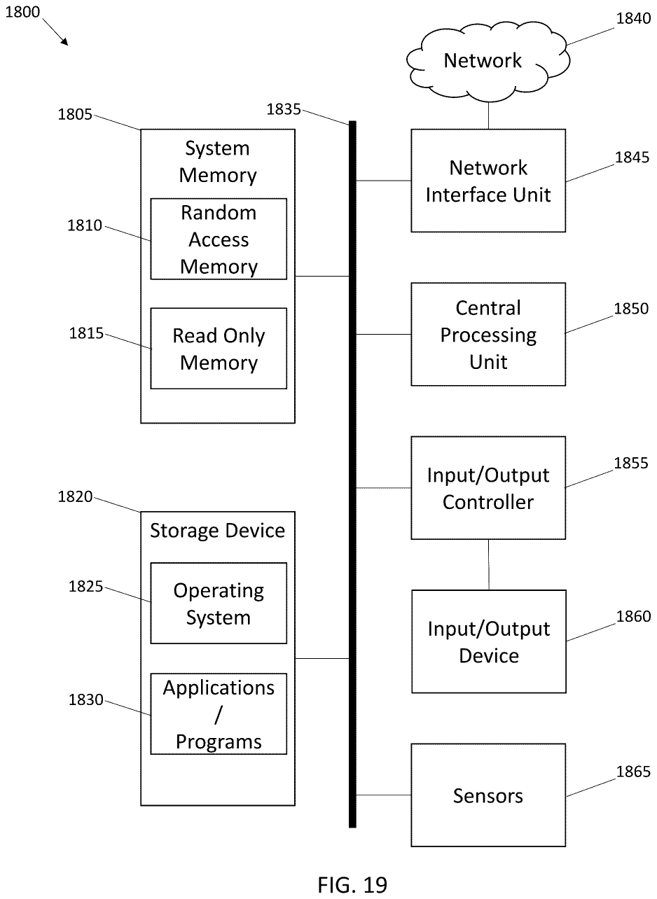

FIG. 19 and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 19 depicts an illustrative computer architecture for a computer 1800 for practicing the various embodiments of the invention. The computer architecture shown in FIG. 19 illustrates a conventional personal computer, including a central processing unit 1850 (“CPU”), a system memory 1805, including a random-access memory 1810 (“RAM”) and a read-only memory (“ROM”) 1815, and a system bus 1835 that couples the system memory 1805 to the CPU 1850. A basic input/output system containing the basic routines that help to transfer information between elements within the computer, such as during startup, is stored in the ROM 1815. The computer 1800 further includes a storage device 1820 for storing an operating system 1825, application/program 1830, and data.

The storage device 1820 is connected to the CPU 1850 through a storage controller (not shown) connected to the bus 1835. The storage device 1820 and its associated computer-readable media, provide non-volatile storage for the computer 1800. Although the description of computer-readable media contained herein refers to a storage device, such as a hard disk or CD-ROM drive, it should be appreciated by those skilled in the art that computer-readable media can be any available media that can be accessed by the computer 1800.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 1800 may operate in a networked environment using logical connections to remote computers through a network 1840, such as TCP/IP network such as the Internet or an intranet. The computer 1800 may connect to the network 1840 through a network interface unit 1845 connected to the bus 1835. It should be appreciated that the network interface unit 1845 may also be utilized to connect to other types of networks and remote computer systems.

The computer 1800 may also include an input/output controller 1855 for receiving and processing input from a number of input/output devices 1860, including a keyboard, a mouse, a touchscreen, a camera, a microphone, a controller, a joystick, or other type of input device. Similarly, the input/output controller 1855 may provide output to a display screen, a printer, a speaker, or other type of output device. The computer 1800 can connect to the input/output device 1860 via a wired connection including, but not limited to, fiber optic, ethernet, or copper wire or wireless means including, but not limited to, Bluetooth, Near-Field Communication (NFC), infrared, or other suitable wired or wireless connections.

As mentioned briefly above, a number of program modules and data files may be stored in the storage device 1820 and RAM 1810 of the computer 1800, including an operating system 1825 suitable for controlling the operation of a networked computer. The storage device 1820 and RAM 1810 may also store one or more applications/programs 1830. In particular, the storage device 1820 and RAM 1810 may store an application/program 1830 for providing a variety of functionalities to a user. For instance, the application/program 1830 may comprise many types of programs such as a word processing application, a spreadsheet application, a desktop publishing application, a database application, a gaming application, internet browsing application, electronic mail application, messaging application, and the like. According to an embodiment of the present invention, the application/program 1830 comprises a multiple functionality software application for providing word processing functionality, slide presentation functionality, spreadsheet functionality, database functionality and the like.

The computer 1800 in some embodiments can include a variety of sensors 1865 for monitoring the environment surrounding and the environment internal to the computer 1800. These sensors 1865 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

### REFERENCES

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

The following publications are each hereby incorporated herein by reference in their entirety:
1) K. S. Ng, C.-S. Moo, Y.-P. Chen, Y.-C. Hsieh, Enhanced coulomb counting method for estimating state-of-charge and state-of-health of lithium-ion batteries, Applied energy 86 (9) (2009) 1506-1511.
2) Y. Ghoulam, T. Mesbahi, P. Wilson, S. Durand, A. Lewis, C. Lallement, C. Vagg,
Lithium-ion battery parameter identification for hybrid and electric vehicles using drive cycle data, Energies 15 (11) (2022) 4005.
3) Y. Zheng, M. Ouyang, X. Han, L. Lu, J. Li, Investigating the error sources of the online state of charge estimation methods for lithium-ion batteries in electric vehicles, Journal of Power Sources 377 (2018) 161-188.
4) Y. Xing, W. He, M. Pecht, K. L. Tsui, State of charge estimation of lithium-ion batteries using the open-circuit voltage at various ambient temperatures, Applied Energy 113 (2014) 106-115.
5) D. Zhang, S. Dey, L. D. Couto, S. J. Moura, Battery adaptive observer for a single particle model with intercalation-induced stress, IEEE Trans Control Syst Technol 28 (4) (2019) 1363-1377.
6) X. Han, M. Ouyang, L. Lu, J. Li, Simplification of physics-based electrochemical model for lithium-ion battery on electric vehicle. Part I: Diffusion simplification and single particle model, J. Power Sources 278 (2015) 802-813.
7) S. Park, D. Zhang, R. Klein, S. Moura, Estimation of cyclable lithium for li-ion battery state-of-health monitoring, in: ACC 21, IEEE, 2021, pp. 3094-3101.
8) M. Doyle, Modeling of Galvanostatic Charge and Discharge of the Lithium/Polymer/Insertion Cell, Journal of The Electrochemical Society 140 (6) (1993) 1526.
9) W. Gu, C. Wang, Thermal-electrochemical modeling of battery systems, Journal of The Electrochemical Society 147 (8) (2000) 2910.
10) P. Ramadass, B. Haran, P. M. Gomadam, R. White, B. N. Popov, Development of first principles capacity fade model for li-ion cells, Journal of the Electrochemical Society 151 (2) (2004) A196.
11) P. Arora, M. Doyle, R. E. White, Mathematical modeling of the lithium deposition overcharge reaction in lithium-ion batteries using carbon-based negative electrodes, Journal of The Electrochemical Society 146 (10) (1999) 3543.
12) M. Ecker, T. K. D. Tran, P. Dechent, S. K″abitz, A. Warnecke, D. U. Sauer, Parameterization of a Physico-Chemical Model of a Lithium-Ion Battery: I. Determination of Parameters, J. Electrochem. Soc. 162 (9) (2015) A1836-A1848.
13) N. A. Chaturvedi, R. Klein, J. Christensen, J. Ahmed, A. Kojic, Algorithms for advanced battery-management systems, IEEE Control Syst. 30 (3) (2010) 49-68.
14) M. M. Majdabadi, S. Farhad, M. Farkhondeh, R. A. Fraser, M. Fowler, Simplified electrochemical multi-particle model for lifepo4 cathodes in lithium ion batteries, Journal of Power Sources 275 (2015) 633-643.
15) S. Park, D. Kato, Z. Gima, R. Klein, S. Moura, Optimal experimental design for parameterization of an electrochemical lithium-ion battery model, J. Electrochem. Soc. 165 (7) (2018) A1309.
16) U. Krewer, F. R″oder, E. Harinath, R. D. Braatz, B. Bedu″rftig, R. Findeisen, Dynamic models of li-ion batteries for diagnosis and operation: a review and perspective, Journal of the electrochemical society 165 (16) (2018) A3656.
17) X. Hu, S. Li, H. Peng, A comparative study of equivalent circuit models for li-ion batteries, Journal of Power Sources 198 (2012) 359-367.
18) X. Lin, Y. Kim, S. Mohan, J. B. Siegel, A. G. Stefanopoulou, Modeling and estimation for advanced battery management, Annual Review of Control, Robotics, and Autonomous Systems 2 (2019) 393-426.
19) H. He, R. Xiong, X. Zhang, F. Sun, J. Fan, State-of-charge estimation of the lithium-ion battery using an adaptive extended kalman filter based on an improved Thevenin model, IEEE Transactions on vehicular technology 60 (4) (2011) 1461-1469.
20) X. Lin, Y. Tang, J. Ren, Y. Wei, State of charge estimation with the adaptive unscented kalman filter based on an accurate equivalent circuit model, Journal of Energy Storage 41 (2021) 102840.
21) C. Jiang, S. Wang, B. Wu, C. Fernandez, X. Xiong, J. Coffie-Ken, A state of-charge estimation method of the power lithium-ion battery in complex conditions based on adaptive square root extended kalman filter, Energy 219 (2021) 119603.
22) A. Sancarlos, M. Cameron, A. Abel, E. Cueto, J.-L. Duval, F. Chinesta, From rom of electrochemistry to ai-based battery digital and hybrid twin, Archives of Computational Methods in Engineering 28 (3) (2021) 979-1015.
23) M. A. Patil, P. Tagade, K. S. Hariharan, S. M. Kolake, T. Song, T. Yeo, S. Doo, A novel multistage support vector machine-based approach for li ion battery remaining useful life estimation, Applied energy 159 (2015) 285-297.
24) X. Feng, C. Weng, X. He, X. Han, L. Lu, D. Ren, M. Ouyang, Online state of-health estimation for li-ion battery using partial charging segment based on support vector machine, IEEE Transactions on Vehicular Technology 68 (9) (2019) 8583-8592.
25) E. Chemali, P. J. Kollmeyer, M. Preindl, A. Emadi, State-of-charge estimation of Li-ion batteries using deep neural networks: A machine learning approach, J. Power Sources 400 (2018) 242-255.
26) D. N. How, M. A. Hannan, M. S. H. Lipu, K. S. Sahari, P. J. Ker, K. M. Muttaqi, State-of-charge estimation of li-ion battery in electric vehicles: A deep neural network approach, IEEE Transactions on Industry Applications 56 (5) (2020) 5565-5574.
27) D. Zhu, J. J. Campbell, G. Cho, Battery voltage prediction using neural networks, in: 2021 IEEE Transportation Electrification Conference & Expo (ITEC), IEEE, 2021, pp. 807-812.
28) C. Vidal, P. Malysz, M. Naguib, A. Emadi, P. J. Kollmeyer, Estimating battery state of charge using recurrent and non-recurrent neural networks, Journal of Energy Storage 47 (2022) 103660.
29) R. Zhao, P. J. Kollmeyer, R. D. Lorenz, T. M. Jahns, A compact unified methodology via a recurrent neural network for accurate modeling of lithium-ion battery voltage and state-of-charge, in: 2017 IEEE Energy Conversion Congress and Exposition (ECCE), IEEE, 2017, pp. 5234-5241.
30) X. Fan, W. Zhang, C. Zhang, A. Chen, F. An, Soc estimation of li-ion battery using convolutional neural network with u-net architecture, Energy 256 (2022) 124612.
31) C. Bian, S. Yang, Q. Miao, Cross-domain state-of-charge estimation of li-ion batteries based on deep transfer neural network with multiscale distribution adaptation, IEEE Transactions on Transportation Electrification 7 (3) (2021) 1260-1270.
32) X. Hu, S. E. Li, Y. Yang, Advanced machine learning approach for lithium ion battery state estimation in electric vehicles, IEEE Transactions on Transportation Electrification 2 (2) (2016) 140-149.
33) H. Tu, S. Moura, H. Fang, Integrating electrochemical modeling with machine learning for lithium-ion batteries, in: 2021 American Control Conference (ACC), 2021, pp. 4401-4407.
34) Z. Cui, L. Kang, L. Li, L. Wang, K. Wang, A combined state-of-charge estimation method for lithium-ion battery using an improved bgru network and ukf, Energy 259 (2022) 124933.
35) H. Tu, S. Moura, Y. Wang, H. Fang, Integrating physics-based modeling with machine learning for lithium-ion batteries, Applied Energy 329 (2023) 120289.
36) S. Su, W. Li, J. Mou, A. Garg, L. Gao, J. Liu, A hybrid battery equivalent circuit model, deep learning, and transfer learning for battery state monitoring, IEEE Transactions on Transportation Electrification 9 (1) (2022) 1113-1127.
37) Q.-K. Wang, Y.-J. He, J.-N. Shen, Z.-F. Ma, G.-B. Zhong, A unified modeling framework for lithium-ion batteries: An artificial neural network based thermal coupled equivalent circuit model approach, Energy 138 (2017) 118-132.
38) S. Park, D. Zhang, S. Moura, Hybrid electrochemical modeling with recurrent neural networks for li-ion batteries, in: 2017 American control conference (ACC), IEEE, 2017, pp. 3777-3782.
39) F. Feng, S. Teng, K. Liu, J. Xie, Y. Xie, B. Liu, K. Li, Co-estimation of lithium-ion battery state of charge and state of temperature based on a hybrid electrochemical-thermal-neural-network model, Journal of Power Sources 455 (2020) 227935.
40) S. L. Brunton, J. L. Proctor, J. N. Kutz, Discovering governing equations from data by sparse identification of nonlinear dynamical systems, PNAS 113 (15) (2016) 3932-3937.
41) O. Ahmadzadeh, R. Rodriguez, Y. Wang, D. Soudbakhsh, A physics inspired machine learning nonlinear model of li-ion batteries, in: 2023 American Control Conference (ACC), IEEE, 2023, pp. 3087-3092.
42) D. Soudbakhsh, A. M. Annaswamy, Y. Wang, S. L. Brunton, J. Gaudio, H. Hussain, D. Vrabie, J. Drgona, D. Filev, Data-Driven Control: Theory and Applications, in: ACC'2023, 2023, pp. 1922-1939.
43) E. A. Wan, R. Van Der Merwe, The unscented Kalman filter for nonlinear estimation, in: Proceedings of the IEEE 2000 Adaptive Systems for Signal Processing, Communications, and Control Symposium (Cat. No. 00EX373), Ieee, 2000, pp. 153-158.
44) S. L. Brunton, J. L. Proctor, J. N. Kutz, Sparse identification of nonlinear dynamics with control (SINDYc), IFAC-PapersOnLine 49 (18) (2016) 710-715.
45) U. Fasel, E. Kaiser, J. N. Kutz, B. W. Brunton, S. L. Brunton, Sindy with control: A tutorial, in: 2021 60th IEEE Conference on Decision and Control (CDC), IEEE, 2021, pp. 16-21.
46) E. Kaiser, J. N. Kutz, S. L. Brunton, Sparse identification of nonlinear dynamics for model predictive control in the low-data limit, Proceedings of the Royal Society A 474 (2219) (2018) 20180335.
47) K. Kaheman, J. N. Kutz, S. L. Brunton, Sindy-pi: a robust algorithm for parallel implicit sparse identification of nonlinear dynamics, Proceedings of the Royal Society A 476 (2242) (2020) 20200279.
48) A. A. Kaptanoglu, J. L. Callaham, A. Aravkin, C. J. Hansen, S. L. Brunton, Promoting global stability in data-driven models of quadratic nonlinear dynamics, Physical Review Fluids 6 (9) (2021) 094401.
49) U. Fasel, J. N. Kutz, B. W. Brunton, S. L. Brunton, Ensemble-sindy: Robust sparse model discovery in the low-data, high-noise limit, with active learning and control, Proceedings of the Royal Society A 478 (2260) (2022) 20210904.
50) K. Kaheman, S. L. Brunton, J. N. Kutz, Automatic differentiation to simultaneously identify nonlinear dynamics and extract noise probability distributions from data, Machine Learning: Science and Technology 3 (1) (2022) 015031.
51) J. Wang, J. Moreira, Y. Cao, B. Gopaluni, Time-variant digital twin modeling through the kalman-generalized sparse identification of nonlinear dynamics, in: 2022 American Control Conference (ACC), IEEE, 2022, pp. 5217-5222.
52) S. H. Rudy, S. L. Brunton, J. L. Proctor, J. N. Kutz, Data-driven discovery of partial differential equations, Science advances 3 (4) (2017) e1602614.
53) O. Ahmadzadeh, R. Rodriguez, D. Soudbakhsh, Modeling of li-ion batteries for real-time analysis and control: A data-driven approach, in: 2022 American Control Conference (ACC), IEEE, 2022, pp. 392-397.
54) E. A. Wan, R. Van Der Merwe, The unscented kalman filter, Kalman filtering and neural networks (2001) 221-280.
55) J. M. Reniers, G. Mulder, D. A. Howey, Review and performance comparison of mechanical-chemical degradation models for lithium-ion batteries, Journal of The Electrochemical Society 166 (14) (2019) A3189.
56) OAR. US EPA, Dynamometer Drive Schedules, https://www.epa.gov/vehicle-and-fuel-emissions-testing/dynamometerdrive-schedules (September 2015).
57) R. Rodriguez, O. Ahmadzadeh, Y. Wang, D. Soudbakhsh, Discovering Governing Equations of Li-ion Batteries Pertaining State of Charge Using Input-Output Data, in: ACC'2023, San Diego, CA, USA, 2023.
58) N. M. Mangan, J. N. Kutz, S. L. Brunton, J. L. Proctor, Model selection for dynamical systems via sparse regression and information criteria, Proceedings of the Royal Society A: Mathematical, Physical and Engineering Sciences 473 (2204) (2017)

What is claimed is:

1. A battery state-of-charge (SOC) estimation method, comprising:
applying an input to the battery comprising at least one of a voltage, a current, or a temperature;
receiving battery data from at least one sensor associated with the battery, comprising a battery voltage, a battery current, or a battery temperature;
applying a model based on equations based on electrochemistry of the battery to the received battery data; and
calculating an estimated SOC.

2. The method of claim 1, where the model is continuously updated and learns over time.

3. The method of claim 1, further comprising calculating a battery voltage.

4. The method of claim 1, further comprising calculating a state-of-health (SOH) of the battery.

5. The method of claim 1, wherein the method is non-invasive.

6. The method of claim 1, wherein the method is non-destructive.

7. The method of claim 1, wherein the method is performed on a battery in its operating condition.

8. The method of claim 1, wherein the input is sinusoidal.

9. The method of claim 1, wherein the model comprises a data-driven reduced order nonlinear model.

10. The method of claim 1, wherein the model is built via sparsification via sequentially thresholding ridge regression combined with a joint unscented Kalman filter.

11. The method of claim 1, where the model is tuned via a cost function.

12. A battery state-of-charge (SOC) estimation system, comprising:
at least one sensor associated with a battery; and
a computing system communicatively connected to the at least one sensor, comprising a processor and a non-transitory computer-readable medium with instructions stored thereon, which when executed by the processor, perform steps comprising:
receiving battery data from the at least one sensor associated with the battery due to an input being applied, comprising a battery voltage, a battery current, or a battery temperature;
applying a model based on equations based on electrochemistry of the battery to the received battery data; and
calculating an estimated SOC.

13. The system of claim 12, where the at least one sensor comprises at least one of a voltage meter, a current meter, a thermometer, an electrical impedance meter, or an electrical resistance meter.

14. A battery state-of-charge (SOC) estimation method, comprising:
applying an input to a battery comprising at least one of a voltage or a current;
receiving battery data from at least one sensor associated with the battery, comprising at least one of a battery voltage, a battery current, and a temperature; and
creating a data-driven model of voltage dynamics and SOC dynamics based on applying the received battery data to equations of the battery to estimate the SOC.

15. A non-transitory computer readable medium comprising program instructions for causing a computer to perform a battery state-of-charge (SOC) estimation method comprising:
receiving battery data from at least one sensor associated with the battery due to an input being applied, comprising a battery voltage, a battery current, or a battery temperature;
applying a model based on equations based on electrochemistry of the battery to the received battery data; and
calculating an estimated SOC.
